(19) United States
(12) Patent Application Publication
(10) Pub. No.: US 2025/0107376 A1
(43) Pub. Date: Mar. 27, 2025

(54) DISPLAY PANEL AND DISPLAY APPARATUS

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventors: Rong WANG, Beijing (CN); Fan HE, Beijing (CN); Yi HE, Beijing (CN); Xiangdan DONG, Beijing (CN); Haibo YU, Beijing (CN); Kemeng TONG, Beijing (CN); Qiwei WANG, Beijing (CN); Wenzhe CAI, Beijing (CN)

(21) Appl. No.: 18/713,212

(22) PCT Filed: Aug. 2, 2023
(86) PCT No.: PCT/CN2023/110837

§ 371 Date: May 24, 2024

(30) Foreign Application Priority Data
Aug. 4, 2022 (CN) 202210935801.1

(51) Int. Cl. H10K 59/131; H10K 59/121

(52) U.S. Cl. CPC H10K 59/1315; H10K 59/1213; H10K 59/1216

(57) ABSTRACT

The present disclosure relates to the technical field of display, and provides a display panel and a display apparatus. The display panel includes a display area and a fan-out area located in the display area. The display panel further includes: a base substrate; a plurality of data lines located in the display area; a plurality of first data fan-out lines located in the fan-out area; and a plurality of second data fan-out lines located in the fan-out area.

### CROSS REFERENCE TO RELATED APPLICATION(S)

The present application claims priority to Chinese Patent Application No. 202210935801.1, titled “Display Panel and Display Apparatus” and filed on Aug. 4, 2022, the disclosure of which is incorporated herein in its entirety as part of the present application.

### TECHNICAL FIELD

The present disclosure relates to the field of display technology, and in particular, to a display panel and a display apparatus.

### BACKGROUND

In the related art, the display panel has a wider frame.

It should be noted that the information disclosed in the background section is only used to enhance understanding of the background of the present disclosure, and therefore may include information that does not constitute prior art known to those of ordinary skill in the art.

### SUMMARY

According to an aspect of the present disclosure, a display panel is provided. The display panel includes a display area and a fan-out area located in the display area. The display panel further includes: a base substrate, a plurality of data lines, a plurality of first data fan-out lines, and a plurality of second data fan-out lines. The plurality of data lines is located in the display area. The orthographic projections of the data lines on the base substrate are arranged at intervals along the first direction and extend along the second direction. The first direction intersects the second direction. The plurality of first data fan-out lines is located in the fan-out area. The orthographic projections of the first data fan-out lines on the base substrate are arranged at intervals along the second direction and extend along the first direction. The first data fan-out line is provided corresponding to a respective data line. The first data fan-out line is connected to the respective data line. The plurality of second data fan-out lines is located in the fan-out area. The orthographic projections of the second data fan-out lines on the base substrate are arranged at intervals along the first direction and extend along the second direction. The second data fan-out line is arranged corresponding to a respective first data fan-out line. The second data fan-out line is connected to the respective first data fan-out line.

In an exemplary embodiment of the present disclosure, the display panel further includes a plurality of first signal lines and a plurality of second signal lines. The plurality of first signal lines is located in the display area. The orthographic projections of the first signal lines on the base substrate extend along the first direction and are arranged at intervals along the second direction. The plurality of first signal lines includes a first signal sub-line. At least a partial structure of the first signal sub-line is used to form the first data fan-out line. The plurality of second signal lines is located in the display area, and is arranged on a different conductive layer from the first signal lines. The orthographic projections of the second signal lines on the base substrate extend along the second direction and are arranged at intervals along the first direction. The plurality of second signal lines includes a second signal sub-line. At least a partial structure of the second signal sub-line is used to form the second data fan-out line.

In an exemplary embodiment of the present disclosure, the minimum distance in the second direction between the orthographic projections of two adjacent first signal lines on the base substrate is S1, and the maximum distance in the second direction between the orthographic projections of two adjacent first signal lines on the base substrate is S2, where (S2−S1)/S1 is greater than or equal to 0 and less than or equal to 0.2. Additionally or alternatively, the minimum distance in the first direction between the orthographic projections of two adjacent second signal lines on the base substrate is S3, and the maximum distance in the first direction between the orthographic projections of two adjacent second signal lines on the base substrate is S4, where (S4−S3)/S3 is greater than or equal to 0 and less than or equal to 0.2.

In an exemplary embodiment of the present disclosure, the first signal sub-line further includes a first simulation line spaced apart from the first data fan-out line, and the second signal sub-line further includes a second simulation line spaced apart from the second data fan-out line. The fan-out area includes a first fan-out area and a second fan-out area. The first data fan-out line is located in the first fan-out area. The second data fan-out line is located in the second fan-out area. The plurality of first signal lines also includes a third simulation line. The third simulation line is located in the display area outside the first fan-out area. The plurality of second signal lines also includes a fourth simulation line. The fourth simulation line is located in the display area outside the second fan-out area.

In an exemplary embodiment of the present disclosure, the display panel further includes a pixel driving circuit and a light-emitting unit. The pixel driving circuit is connected to the first electrode of the light-emitting unit. The display panel further includes a common electrode layer. The common electrode layer is used to form the second electrode of the light-emitting unit. The first simulation line, the second simulation line, the third simulation line, and the fourth simulation line are connected to the common electrode layer.

In an exemplary embodiment of the present disclosure, the first simulation line is connected through a via hole to the fourth simulation line that intersects the orthographic projection of the first simulation line on the base substrate. The third simulation line is connected through via holes to the second simulation line and the fourth simulation line that intersect the orthographic projection of the third simulation line on the base substrate.

In an exemplary embodiment of the present disclosure, the display panel further includes a frame area located around the display area. The frame area includes a first frame area and a second frame area arranged oppositely. The fan-out area is located at a side close to the second frame area. The display panel also includes an electrode ring and a power circuit. The electrode ring is located in the frame area and connected to the common electrode layer. At least a partial structure of the electrode ring located in the first frame area connects the second simulation line and the fourth simulation line. The power circuit is bound to the second frame area. The power circuit is connected to at least a partial structure of the electrode ring located in the second frame area. The power circuit is used to provide a power signal to the electrode ring.

In an exemplary embodiment of the present disclosure, the first fan-out area includes a first fan-out sub-area and a second fan-out sub-area. The first fan-out sub-area and the second fan-out sub-area are located at both sides in the first direction of the second fan-out area. The plurality of second signal lines also includes at least one fifth simulation line. A partial structure of the fifth simulation line is located in the second fan-out area. The fifth simulation line is respectively connected through via holes to the first simulation line and the third simulation line that intersect the orthographic projection of the fifth simulation line on the base substrate.

In an exemplary embodiment of the present disclosure, the plurality of first signal lines is located on the same conductive layer, and the plurality of second signal lines is located on the same conductive layer. The conductive layer where the second signal line is located is arranged on a side away from the base substrate of the conductive layer where the first signal line is located.

In an exemplary embodiment of the present disclosure, the display panel further includes a first source-drain layer and a second source-drain layer. The first source-drain layer is located on one side of the base substrate. The first source-drain layer includes the first signal line. The second source-drain layer is located on a side of the first source-drain layer away from the base substrate. The second source-drain layer includes the second signal line and the data line. The orthographic projection of the second signal line on the base substrate is located between the orthographic projections of two adjacent data lines on the base substrate.

In an exemplary embodiment of the present disclosure, the first signal line includes a plurality of first via contact portions and a first extension portion. The orthographic projections of the plurality of first via contact portions on the base substrate are arranged at intervals along the first direction. The first extension portion is connected to the first via contact portion. The orthographic projection of the first via contact portion on the base substrate has a dimension in the second direction, which is greater than the dimension in the second direction of the orthographic projection of the first extension portion on the base substrate. The second signal line includes a plurality of second via contact portions and a second extension portion. The orthographic projections of the plurality of second via contact portions on the base substrate are arranged at intervals along the second direction. The second extension portion is connected to the second via contact portion. The dimension in the first direction of the orthographic projection of the second via contact portion on the base substrate is larger than the dimension in the first direction of the orthographic projection of the second extension portion on the base substrate. The first via contact portion is arranged corresponding to a respective second via contact portion. The orthographic projection of the first via contact portion on the base substrate at least partially overlaps with the orthographic projection of the respective second via contact portion on the base substrate. At least some of the first via contact portions are connected to the respective second via contact portions through via holes.

In an exemplary embodiment of the present disclosure, the minimum distance in the first direction between the orthographic projections of adjacent first via contact portions on the base substrate is S5, and the maximum distance in the first direction between the orthographic projections of adjacent first via contact portions on the base substrate is S6, where (S6−S5)/S5 is greater than or equal to 0 and less than or equal to 0.2. Additionally or alternatively, the minimum distance in the second direction between the orthographic projections of adjacent second via contact portions on the base substrate is S7, and the maximum distance in the second direction between the orthographic projections of adjacent second via contact portions on the base substrate is S8, where (S8−S7)/S7 is greater than or equal to 0 and less than or equal to 0.2.

In an exemplary embodiment of the present disclosure, the plurality of first via contact portions includes a first real hole contact portion. The plurality of second via contact portions includes a second real hole contact portion and a second dommy hole contact portion. The first real hole contact portion and the respective second real hole contact portion are connected through a via hole. The second dummy hole contact portion is insulated from the first signal line that intersects the orthographic projection of the second dummy hole contact portion on the base substrate.

In an exemplary embodiment of the present disclosure, the plurality of first via contact portions further include a first dummy hole contact portion. The first dummy hole contact portion and the respective second dummy hole contact portion are insulated.

In an exemplary embodiment of the present disclosure, the display panel includes a first planarization layer. The first planarization layer is located between the first source-drain layer and the second source-drain layer. The first planarization layer has a thickness less than or equal to 1.6 μm.

In an exemplary embodiment of the present disclosure, the display panel further includes a passivation layer and a first planarization layer. The passivation layer is arranged between the conductive layer where the first signal line is located and the conductive layer where the second signal line is located. The first planarization layer is arranged between the passivation layer and the conductive layer where the second signal line is located. A first opening is formed on the first planarization layer. The orthographic projection of the first opening on the base substrate at least partially overlaps with the orthographic projection of the second dummy hole contact portion on the base substrate.

In an exemplary embodiment of the present disclosure, the display panel further includes a passivation layer and a first planarization layer. The passivation layer is arranged between the conductive layer where the first signal line is located and the conductive layer where the second signal line is located. The first planarization layer is arranged between the passivation layer and the conductive layer where the second signal line is located. A second opening is formed on the passivation layer. The orthographic projection of the second opening on the base substrate at least partially overlaps with the orthographic projection of the second dummy hole contact portion on the base substrate.

In an exemplary embodiment of the present disclosure, the dimension in the first direction of the orthographic projection on the base substrate of the notch between the first data fan-out line and the first simulation line is 1.5 um-3.5 um. Additionally or alternatively, the dimension in the second direction of the orthographic projection on the base substrate of the notch between the second data fan-out line and the second simulation line is 1.5 um-3.5 um.

In an exemplary embodiment of the present disclosure, the data line, whose orthographic projection on the base substrate is located on two adjacent sides of the second signal line, includes a third extension portion, a fourth extension portion, and a fifth extension portion. The fourth extension portion is connected between the third extension portion and the fifth extension portion. At least partial structures of the second via contact portion and the fourth extension portion are arranged oppositely in the first direction. The dimensions in the first direction of the orthographic projection of the fourth extension portion on the base substrate and the orthographic projection of the second extension portion on the base substrate are larger than the dimensions in the first direction of the orthographic projection of the third extension portion on the base substrate and the orthographic projection of the second extension portion on the base substrate. The dimensions in the first direction of the orthographic projection of the fourth extension portion on the base substrate and the orthographic projection of the second extension portion on the base substrate are larger than the dimensions in the first direction of the orthographic projection of the fifth extension portion on the base substrate and the orthographic projection of the second extension portion on the base substrate.

In an exemplary embodiment of the present disclosure, the display panel further includes a pixel driving circuit and a light-emitting unit. The pixel driving circuit is connected to the first electrode of the light-emitting unit. The display panel further includes an electrode layer located on one side of the base substrate. The electrode layer includes a plurality of electrode portions. The electrode portion is used to form the first electrode of the light-emitting unit. The orthographic projection of the notch between the first data fan-out line and the first simulation line on the base substrate does not overlap with the orthographic projection of the electrode portion on the base substrate. Additionally or alternatively, the orthographic projection of the notch between the second data fan-out line and the second simulation line on the base substrate does not overlap with the orthographic projection of the electrode portion on the base substrate.

In an exemplary embodiment of the present disclosure, the display panel further includes a pixel driving circuit and a light-emitting unit. The pixel driving circuit is connected to the first electrode of the light-emitting unit. The display panel further includes an electrode layer located on one side of the base substrate. The electrode layer includes a plurality of electrode portions. The electrode portion is used to form the first electrode of the light-emitting unit. The orthographic projection of the first via contact portion on the base substrate and the orthographic projection of the electrode portion on the base substrate do not overlap. Orthographic projections on the base substrate of the second via contact portion and the electrode portion do not overlap.

In an exemplary embodiment of the present disclosure, the display panel further includes a plurality of pixel driving circuits and a plurality of light-emitting units. The plurality of pixel driving circuits is arranged in an array along the first direction and the second direction. The pixel driving circuit is connected to the first electrode of the light-emitting unit. The pixel driving circuit includes a driving transistor, a sixth transistor, and a seventh transistor. The first terminal of the sixth transistor is connected to the second terminal of the driving transistor. The second terminal of the sixth transistor is connected to the first terminal of the light-emitting unit. The first terminal of the seventh transistor is connected to the second initial signal line. The second terminal of the seventh transistor is connected to the first electrode of the light-emitting unit. The display panel also includes a first active layer and a first gate layer. The first active layer is located on one side of the base substrate. The first active layer includes a sixth active portion and a seventh active portion. The sixth active portion is used to form a channel region of the sixth transistor. The seventh active portion is used to form a channel region of the seventh transistor. The first gate layer is located on the side of the first active layer away from the base substrate. The first gate layer includes an enable signal line and a second reset signal line. The orthographic projection of the enable signal line on the base substrate extends along the first direction, and covers the orthographic projection of the sixth active portion on the base substrate. The orthographic projection of the second reset signal line on the base substrate extends along the first direction, and covers the orthographic projection of the seventh active portion on the base substrate. The first direction is the row direction. The orthographic projection of the first signal line on the base substrate is located between the orthographic projection of the enable signal line on the base substrate and the orthographic projection of the second reset signal line on the base substrate in the same row of pixel driving circuits.

In an exemplary embodiment of the present disclosure, the display panel further includes a plurality of pixel driving circuits and a plurality of light-emitting units. The plurality of pixel driving circuits is arranged in an array along the first direction and the second direction. The pixel driving circuit is connected to the first electrode of the light-emitting unit. The pixel driving circuit includes a driving transistor, a sixth transistor, and a first transistor. The first terminal of the sixth transistor is connected to the second terminal of the driving transistor. The second terminal of the sixth transistor is connected to the first electrode of the light-emitting unit. The first terminal of the first transistor is connected to the first initial signal line. The second terminal of the first transistor is connected to the gate of the driving transistor. The display panel also includes a first gate layer and a second gate layer. The first gate layer is located on one side of the base substrate. The first gate layer includes an enable signal line. A partial structure of the enable signal line is used to form the gate of the sixth transistor. The second gate layer is located on the side of the first gate layer away from the base substrate. The second gate layer includes the first initial signal line. The orthographic projection on the base substrate of the first extension portion in the first signal line is located between the orthographic projection on the base substrate of the first initial signal line in the same row of pixel driving circuits and the orthographic projection on the base substrate of the enable signal line in the adjacent next row of pixel driving circuits.

In an exemplary embodiment of the present disclosure, the display panel includes a plurality of repetition units arranged in an array in the first direction and the second direction. The repetition unit includes n rows and m columns of repetition sub-units, where n and m are positive integers greater than or equal to 1. The repetition sub-unit includes two pixel driving circuits arranged adjacently in the first direction. The two pixel driving circuits in the same repetition sub-unit are arranged in mirror symmetry. The plurality of repetition units arranged in the second direction form a column of repetition units. One of the second signal lines is provided between two adjacent columns of repetition units in the first direction. The plurality of repetition units arranged in the first direction form a row of repetition units. Each row of repetition units is provided with a respective first signal line.

In an exemplary embodiment of the present disclosure, the display panel further includes a light-emitting unit. The pixel driving circuit is connected to the first electrode of the light-emitting unit. The display panel further includes an electrode layer. The electrode layer includes a plurality of electrode portions. The electrode portion is used to form the first electrode of the light-emitting unit. Among the two adjacent repetition sub-units in the first direction, the orthographic projections of two adjacent data lines on the base substrate intersect the orthographic projection of the same electrode portion on the base substrate, and are located on both sides of the orthographic projection of the second signal line on the base substrate.

In an exemplary embodiment of the present disclosure, m is a positive integer greater than or equal to 2. Among the adjacent columns of repetition units in the first direction, the minimum distance in the first direction between the orthographic projections of two adjacent data lines on the base substrate is L1. Among the two repetition sub-units located in the same repetition unit and being adjacent in the first direction, the minimum distance in the first direction between the orthographic projections of two adjacent data lines on the base substrate is L2. L1 is greater than L2.

In an exemplary embodiment of the present disclosure, n is a positive integer greater than or equal to 2. The display panel further includes a light-emitting unit. The pixel driving circuit includes a driving transistor, a sixth transistor, and a seventh transistor. The first terminal of the sixth transistor is connected to the second terminal of the driving transistor. The second terminal of the sixth transistor is connected to the first electrode of the light-emitting unit. The gate of the sixth transistor is connected to the enable signal line. The first terminal of the seventh transistor is connected to the second initial signal line. The second terminal of the seventh transistor is connected to the first electrode of the light-emitting unit. The gate of the seventh transistor is connected to the second reset signal line. The same row of repetition units includes a first row of pixel driving circuits and a second row of pixel driving circuits. The first row of pixel driving circuits includes a plurality of pixel driving circuits arranged along the first direction. The second row of pixel driving circuits includes a plurality of pixel driving circuits arranged along the first direction. The orthographic projection of the first signal line on the base substrate is located between the orthographic projection on the base substrate of the enable signal line in the first row of pixel driving circuits and the orthographic projection on the base substrate of the second reset signal line in the first row of pixel driving circuits. In the first row of pixel driving circuits, the minimum distance in the second direction between the orthographic projection of the enable signal line on the base substrate and the orthographic projection of the second reset signal line on the base substrate is L3. In the second row of pixel driving circuits, the minimum distance in the second direction between the orthographic projection of the enable signal line on the base substrate and the orthographic projection of the second reset signal line on the base substrate is L4. L3 is larger than L4.

In an exemplary embodiment of the present disclosure, the display panel includes a pixel driving circuit and a light-emitting unit. The pixel driving circuit includes a driving transistor, a first transistor, a second transistor, a fourth transistor, a fifth transistor, a sixth transistor, a seventh transistor, and a capacitor. The first terminal of the first transistor is connected to the first initial signal line. The second terminal of the first transistor is connected to the gate of the driving transistor. The second transistor has the first terminal connected to the gate of the driving transistor and the second terminal connected to the second terminal of the driving transistor. The fourth transistor has the first terminal connected to the data line and the second terminal connected to the first terminal of the driving transistor. The fifth transistor has the first terminal connected to the power line and the second terminal connected to the first terminal of the driving transistor. The sixth transistor has the first terminal connected to the second terminal of the driving transistor and the second terminal connected to the first electrode of the light-emitting unit. The seventh transistor has the first terminal connected to the second initial signal line and the second terminal connected to the first electrode of the light-emitting unit. The first electrode of the capacitor is connected to the gate of the driving transistor, and the second electrode of the capacitor is connected to the power line.

In an exemplary embodiment of the present disclosure, the display panel further includes a first active layer, a first gate layer, a second active layer, and a third gate layer. The first active layer is located on one side of the base substrate. The first active layer includes a third active portion, a fourth active portion, a fifth active portion, a sixth active portion, and a seventh active portion. The third active portion is used to form a channel region of the driving transistor. The fourth active portion is used to form a channel region of the fourth transistor. The fifth active portion is used to form a channel region of the driving transistor. The sixth active portion is used to form a channel region of the sixth transistor. The seventh active portion is used to form a channel region of the seventh transistor. The first gate layer is located on the side of the first active layer away from the base substrate. The first gate layer includes a first gate line, an enable signal line, a second reset signal line, and a first conductive portion. The orthographic projection of the first gate line on the base substrate extends along the first direction, and covers the orthographic projection of the fourth active portion on the base substrate. The orthographic projection of the enable signal line on the base substrate extends along the first direction, and covers the orthographic projection of the fifth active portion on the base substrate and the orthographic projection of the sixth active portion on the base substrate. The orthographic projection of the second reset signal line on the base substrate extends along the first direction, and covers the orthographic projection of the seventh active portion on the base substrate. The orthographic projection of the first conductive portion on the base substrate covers the orthographic projection of the third active portion on the base substrate. The second active layer is located on the side of the first gate layer away from the base substrate. The second active layer includes a first active portion and a second active portion. The first active portion is used to form a channel region of the first transistor. The second active portion is used to form a channel region of the second transistor. The third gate layer is located on a side of the second active layer away from the base substrate. The third gate layer includes a second gate line and a first reset signal line. The orthographic projection of the second gate line on the base substrate extends along the first direction, and covers the orthographic projection of the second active portion on the base substrate. The orthographic projection of the first reset signal line on the base substrate extends along the first direction, and covers the orthographic projection of the first active portion on the base substrate. The orthographic projection of the second reset signal line on the base substrate, the orthographic projection of the enable signal line on the base substrate, the orthographic projection of the first conductive portion on the base substrate, the orthographic projection of the second gate line on the base substrate, the orthographic projection of the first gate line on the base substrate, and the orthographic projection of the first reset signal line on the base substrate are arranged in sequence along the second direction.

In an exemplary embodiment of the present disclosure, the first direction is the row direction, the second direction is the column direction, and the first gate line in a row of pixel driving circuits is multiplexed as the second reset signal line in the adjacent next row of pixel driving circuits.

In an exemplary embodiment of the present disclosure, the driving transistor, the fourth transistor, the fifth transistor, the sixth transistor, and the seventh transistor are P-type transistors, and the first transistor and the second transistor are N-type transistors.

In an exemplary embodiment of the present disclosure, the second signal line includes a plurality of second via contact portions. The orthographic projections of the plurality of second via contact portions on the base substrate are arranged at intervals along the second direction. In the same second signal line, the distance in the second direction between the orthographic projections of two adjacent second via contact portions on the base substrate is A1. The dimension in the second direction of the orthographic projection of the notch between the second data fan-out line and the second simulation line on the base substrate is A2. A1/A2 is greater than or equal to 27 and less than or equal to 68.

According to an aspect of the present disclosure, a display apparatus is provided, which includes the above-mentioned display panel.

It should be understood that the foregoing general description and the following detailed description are exemplary and explanatory only, and do not limit the present disclosure.

### BRIEF DESCRIPTION OF THE DRAWINGS

The accompanying drawings, which are incorporated in and constitute a part of the present specification, illustrate embodiments consistent with the present disclosure and together with the description, serve to explain the principles of the present disclosure. It is noted that the drawings in the following description are only some embodiments of the present disclosure. For those of ordinary skill in the art, other drawings can be obtained based on these drawings without exerting creative efforts.

FIG. 1 is a schematic structural diagram of a display panel according to an exemplary embodiment of the present disclosure;

FIG. 2 is a schematic structural diagram of a display panel according to another exemplary embodiment of the present disclosure;

FIG. 3 is a partial enlarged view of the first area K1 in FIG. 2;

FIG. 4 is a partial structural layout of the conductive layer where the first signal line is located in FIG. 3;

FIG. 5 is a partial structural layout of the conductive layer where the second signal line is located in FIG. 3;

FIG. 6 is a partial enlarged view of the second area K2 in FIG. 2;

FIG. 7 is a partial structural layout of the conductive layer where the first signal line is located in FIG. 6;

FIG. 8 is a partial structural layout of the conductive layer where the second signal line is located in FIG. 6;

FIG. 9 is a partial enlarged view of the third area K3 in FIG. 2;

FIG. 10 is a partial structural layout of the conductive layer where the first signal line is located in FIG. 9;

FIG. 11 is a partial structural layout of the conductive layer where the second signal line is located in FIG. 9;

FIG. 12 is a partial enlarged view of the fourth area K4 in FIG. 2;

FIG. 13 is a partial structural layout of the conductive layer where the first signal line is located in FIG. 12;

FIG. 14 is a partial structural layout of the conductive layer where the second signal line is located in FIG. 12;

FIG. 15 is a partial enlarged view of the fifth area K5 in FIG. 2;

FIG. 16 is a partial structural layout of the conductive layer where the first signal line is located in FIG. 15;

FIG. 17 is a partial structural layout of the conductive layer where the second signal line is located in FIG. 15;

FIG. 18 is a partial enlarged view of the sixth area K6 in FIG. 2;

FIG. 19 is a partial structural layout of the conductive layer where the first signal line is located in FIG. 18;

FIG. 20 is a partial structural layout of the conductive layer where the second signal line is located in FIG. 18;

FIG. 21 is a partial enlarged view of the seventh area K7 in FIG. 2;

FIG. 22 is a structural layout of the conductive layer where the first signal line is located in FIG. 21;

FIG. 23 is a structural layout of the conductive layer where the second signal line is located in FIG. 21;

FIG. 24 is a structural layout of a display panel according to another exemplary embodiment of the present disclosure;

FIG. 25 is a structural layout of the conductive layer where the first signal line is located in FIG. 24;

FIG. 26 is a structural layout of the conductive layer where the second signal line is located in FIG. 24;

FIG. 27 is a structural layout of the electrode layer in FIG. 24;

FIG. 28 is a partial cross-sectional view of the display panel shown in FIG. 3 along the dotted line CC;

FIG. 29 is a schematic structural diagram of a display panel according to another exemplary embodiment of the present disclosure;

FIG. 30 is a schematic structural diagram of a display panel according to another exemplary embodiment of the present disclosure;

FIG. 31 is a schematic structural diagram of a display panel according to another exemplary embodiment of the present disclosure;

FIG. 32 is a schematic circuit structure diagram of the pixel driving circuit in the display panel according to an embodiment of the present disclosure;

FIG. 33 is a timing diagram of each node in a driving method of the pixel driving circuit in FIG. 32;

FIG. 34 is a partial layout of the sixth area K6 in FIG. 2;

FIG. 35 is the structural layout of the shielding layer in FIG. 34;

FIG. 36 is a structural layout of the first active layer in FIG. 34;

FIG. 37 is a structural layout of the first gate layer in FIG. 34;

FIG. 38 is a structural layout of the second gate layer in FIG. 34;

FIG. 39 is a structural layout of the second active layer in FIG. 34;

FIG. 40 is a structural layout of the third gate layer in FIG. 34;

FIG. 41 is a structural layout of the first source-drain layer in FIG. 34;

FIG. 42 is a structural layout of the second source-drain layer in FIG. 34;

FIG. 43 is a structural layout of the electrode layer in FIG. 34;

FIG. 44 is a structural layout of the shielding layer and the first active layer in FIG. 34;

FIG. 45 is a structural layout of the shielding layer, the first active layer, and the first gate layer in FIG. 34;

FIG. 46 is a structural layout of the shielding layer, the first active layer, the first gate layer, and the second gate layer in FIG. 34;

FIG. 47 is a structural layout of the shielding layer, the first active layer, the first gate layer, the second gate layer, and the second active layer in FIG. 34;

FIG. 48 is a structural layout of the shielding layer, the first active layer, the first gate layer, the second gate layer, the second active layer, and the third gate layer in FIG. 34;

FIG. 49 is a structural layout of the shielding layer, the first active layer, the first gate layer, the second gate layer, the second active layer, the third gate layer, and the first source-drain layer in FIG. 34;

FIG. 50 shows a structural layout of the shielding layer, the first active layer, the first gate layer, the second gate layer, the second active layer, the third gate layer, the first source-drain layer, and the second source-drain layer in FIG. 34;

FIG. 51 is a structural layout of a single repetition unit in FIG. 34;

FIG. 52 is a structural layout of the shielding layer in FIG. 51;

FIG. 53 is a structural layout of the first active layer in FIG. 51;

FIG. 54 is a structural layout of the first gate layer in FIG. 51;

FIG. 55 is a structural layout of the second gate layer in FIG. 51;

FIG. 56 is a structural layout of the second active layer in FIG. 51;

FIG. 57 is a structural layout of the third gate layer in FIG. 51;

FIG. 58 is a structural layout of the first source-drain layer in FIG. 51;

FIG. 59 is a structural layout of the second source-drain layer in FIG. 51;

FIG. 60 is a structural layout of the electrode layer in FIG. 51;

FIG. 61 is a structural layout of the shielding layer and the first active layer in FIG. 51;

FIG. 62 is a structural layout of the shielding layer, the first active layer, and the first gate layer in FIG. 51;

FIG. 63 is a structural layout of the shielding layer, the first active layer, the first gate layer, and the second gate layer in FIG. 51;

FIG. 64 is a structural layout of the shielding layer, the first active layer, the first gate layer, the second gate layer, and the second active layer in FIG. 51;

FIG. 65 is a structural layout of the shielding layer, the first active layer, the first gate layer, the second gate layer, the second active layer, and the third gate layer in FIG. 51;

FIG. 66 is a structural layout of the shielding layer, the first active layer, the first gate layer, the second gate layer, the second active layer, the third gate layer, and the first source-drain layer in FIG. 51;

FIG. 67 shows a structural layout of the shielding layer, the first active layer, the first gate layer, the second gate layer, the second active layer, the third gate layer, the first source-drain layer, and the second source-drain layer in FIG. 51; and

FIG. 68 is a partial cross-sectional view of the display panel shown in FIG. 51 taken along the dotted line EE.

### DETAILED DESCRIPTION OF THE EMBODIMENTS

Example embodiments will now be described more fully with reference to the accompanying drawings. Example embodiments may, however, be embodied in various forms and should not be construed as limited to the examples set forth herein. Rather, these embodiments are provided so that the present disclosure will be thorough and complete and will fully convey the concepts of the example embodiments to those skilled in the art. The same reference numerals in the drawings indicate the same or similar structures, and thus their detailed descriptions will be omitted.

The terms “a”, “an”, and “the” are used to indicate the existence of one or more elements or components, etc. The terms “include” and “have” are used to indicate an open-ended inclusion and refer that additional elements or components, etc. may exist in addition to those listed.

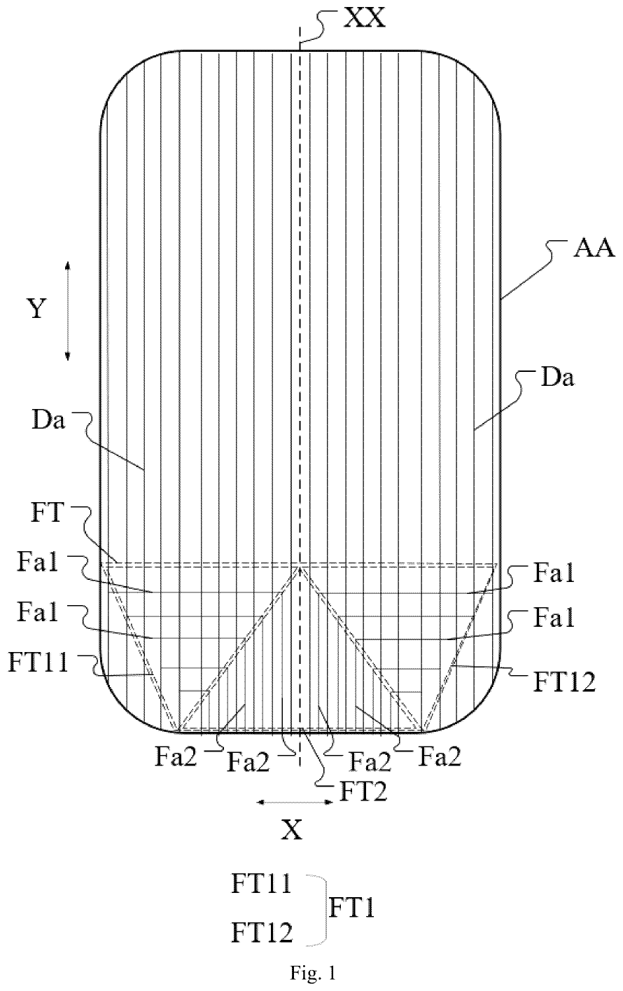

As shown in FIG. 1, it is a schematic structural diagram of a display panel according to an exemplary embodiment of the present disclosure. The display panel may include a display area AA, and a fan-out area FT located in the display area AA. The display panel also includes a base substrate, a plurality of data lines Da, first data fan-out lines Fa1, and second data fan-out lines Fa2. The data lines Da are located in the display area AA. The orthographic projections of the data lines Da on the base substrate are arranged at intervals along the first direction X, and extend along the second direction Y. The first direction X and the second direction Y may intersect. For example, the first direction X may be the row direction, and the second direction Y may be the column direction. The first data fan-out lines Fa1 are located in the fan-out area FT. The orthographic projections of the first data fan-out lines Fa1 on the base substrate may be arranged at intervals along the second direction Y, and extend along the first direction X. The first data fan-out line Fa1 is provided corresponding to a respective data line Da, and the first data fan-out line Fa1 is connected to the respective data line Da. The second data fan-out lines Fa2 are located in the fan-out area FT. The orthographic projections of the second data fan-out lines Fa2 on the base substrate are arranged at intervals along the first direction X, and extend along the second direction Y. The second data fan-out line Fa2 is provided corresponding to a respective first data fan-out line Fa1, and the second data fan-out line Fa2 is connected to the respective first data fan-out line Fa1. The display panel provided by an exemplary embodiment has the fan-out area arranged in the display area, avoiding the provision of the fan-out area in the frame area, thereby reducing the area of the lower frame and the lower corner area of the display panel, and achieving a narrow frame arrangement.

As shown in FIG. 1, the separation line XX separates the display area AA into two display areas arranged in the first direction X. The data line Da on the side away from the separation line XX is connected to the second data fan-out line Fa2 on the side close to the separation line XX through the first data fan-out line Fa1. The fan-out area FT may include a first fan-out area FT1 and a second fan-out area FT2. The first data fan-out line Fa1 is located in the first fan-out area FT1, and the second data fan-out line Fa2 is located in the second fan-out area FT2. The first fan-out area FT1 may include a first fan-out sub-area FT11 and a second fan-out sub-area FT12. The first fan-out sub-area FT11 and the second fan-out sub-area FT12 are located on both sides in the first direction X of the second fan-out area FT2.

It should be understood that in other exemplary embodiments, the first data fan-out line Fa1 and the second data fan-out line Fa2 may also be arranged in other ways. For example, the data line Da on the side close to the separation line XX is connected to the second data fan-out line Fa2 on the side close to the separation line XX through the first data fan-out line Fa1. Alternatively, the data line Da on the side away from the separation line XX is connected to the second data fan-out line Fa2 on the side away from the separation line XX through the first data fan-out line Fa2. For another example, the length of the first data fan-out line Fa1 may also gradually increase from the upper frame to the lower frame.

In this exemplary embodiment, the display panel is provided with a first data fan-out line Fa1 and a second data fan-out line Fa2 in the fan-out area FT, and the first data fan-out line Fa1 and the second data fan-out line Fa2 are not provided in the display area outside the fan-out area FT. The first data fan-out line Fa1 and the second data fan-out line Fa2 have light-reflecting and light-shielding effects. Thus, when the display panel is in the screen-off state, the fan-out area and other display areas of the display panel have different light-reflecting and light-transmitting effects, resulting in a dark shadow on the display panel.

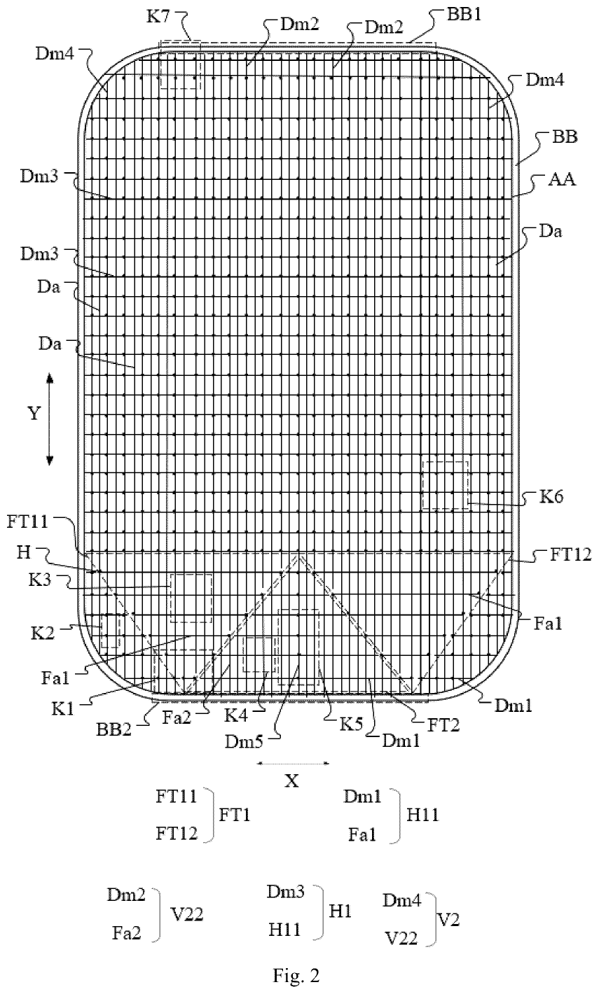

In view of above, an exemplary embodiment also provides another display panel, as shown in FIG. 2, which is a schematic structural diagram of the display panel according to another exemplary embodiment of the present disclosure. The display panel may include a plurality of first signal lines H1 and a plurality of second signal lines V2. The first signal lines H1 are located in the display area AA. The orthographic projections of the first signal lines H1 on the base substrate extend along the first direction X, and are arranged at intervals along the second direction Y. The plurality of first signal lines H1 includes a first signal sub-line H11 and a third simulation line Dm3. The first signal sub-line H11 includes a first data fan-out line Fa1 and a first simulation line Dm1 arranged at intervals. The third simulation line Dm3 is located in the display area AA outside the first fan-out area FT1. The second signal line V2 is located in the display area AA. The second signal line V2 and the first signal line H1 are located on different conductive layers. The orthographic projections of the second signal lines V2 on the base substrate extend along the second direction Y, and are arranged at intervals along the first direction X. The plurality of second signal lines V2 includes a second signal sub-line V22 and a fourth simulation line Dm4. The second signal sub-line V22 includes a second data fan-out line Fa2 and a second simulation line Dm2 arranged at intervals. The fourth simulation line Dm4 is located in the display area AA outside the second fan-out area FT2.

As shown in FIG. 2, according to this exemplary embodiment, the provision of the first simulation line Dm1, the second simulation line Dm2, the third simulation line Dm3, and the fourth simulation line Dm4 helps to make the density of signal lines in the entire display area AA to be closely consistent, thus solving the technical problem of dark shadow mentioned above. It should be noted that when the first data fan-out line Fa1 and the second data fan-out line Fa2 are arranged in other ways, the present disclosure can also eliminate the above dark shadow by providing the simulation lines.

In an exemplary embodiment, the plurality of first signal lines H1 may be located on the same conductive layer, and the plurality of second signal lines V2 may be located on the same conductive layer. The conductive layer where the second signal line V2 is located may be arranged on the side away from the base substrate of the conductive layer where the first signal line H1 is located. For example, the first signal line H1 may be located on the first source-drain layer of the display panel, and the second signal line V2 may be located on the second source-drain layer of the display panel. In addition, the data line Da may also be located on the second source-drain layer of the display panel. The orthographic projection of the second signal line V2 on the base substrate may be located between the orthographic projections of two adjacent data lines Da on the base substrate.

It should be understood that in other exemplary embodiments, the first signal line and the second signal line may also be located on other conductive layers. For example, the first signal line may also be located on the first gate layer, the second gate layer, or the third gate layer in the display panel. The first signal line and the second signal line may also be located on an additional conductive layer. In addition, the first signal line and the second signal line may also be located on the same conductive layer.

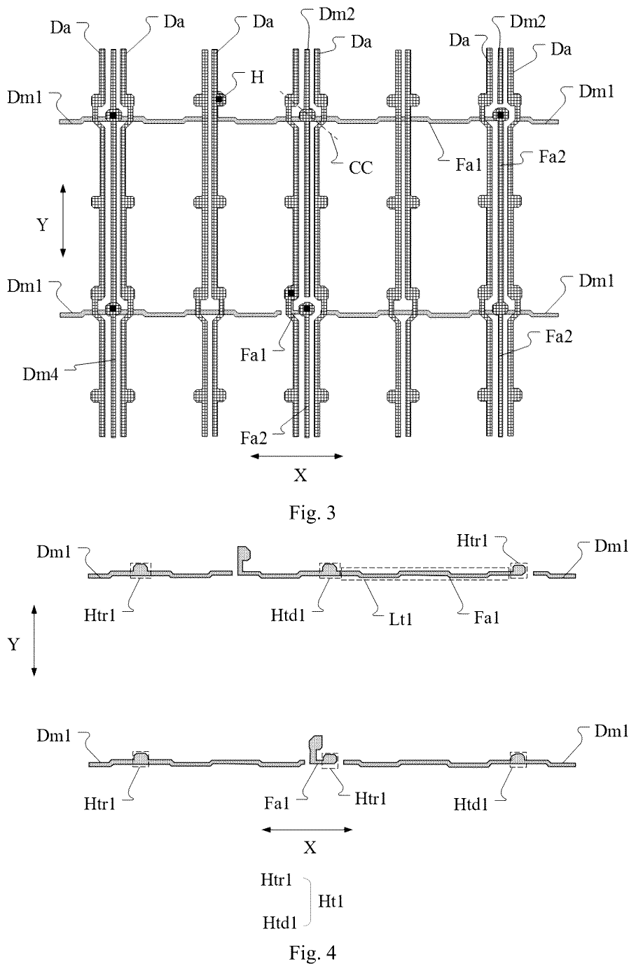

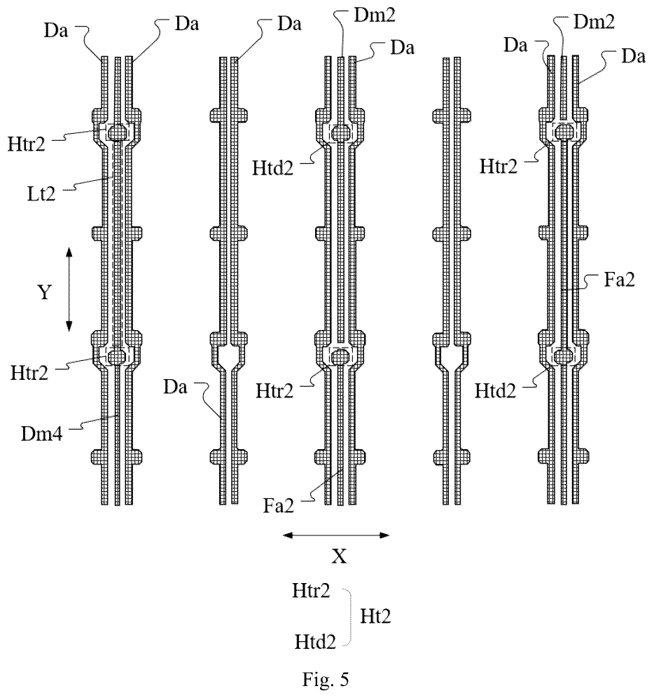

As shown in FIGS. 3, 4, and 5, FIG. 3 is a partially enlarged view of the first area K1 in FIG. 2, FIG. 4 is a partial structural layout of the conductive layer where the first signal line is located in FIG. 3, and FIG. 5 is a partial structural layout of the conductive layer where the second signal line is located in FIG. 3. The first area K1 is partially located in the first fan-out sub-area FT11, the first area K1 is partially located in the second fan-out area FT2, and the first area K1 is partially located in the display area where the first fan-out sub-area FT11 is away from the second fan-out area FT2. As shown in FIGS. 2-5, the first data fan-out line Fa1 may be connected to the data line Da through a via hole H, and connected to the second data fan-out line Fa2 through a via hole. The black circle in FIG. 2 represents the location of the via hole, and the black square in FIG. 3 represents the location of the via hole.

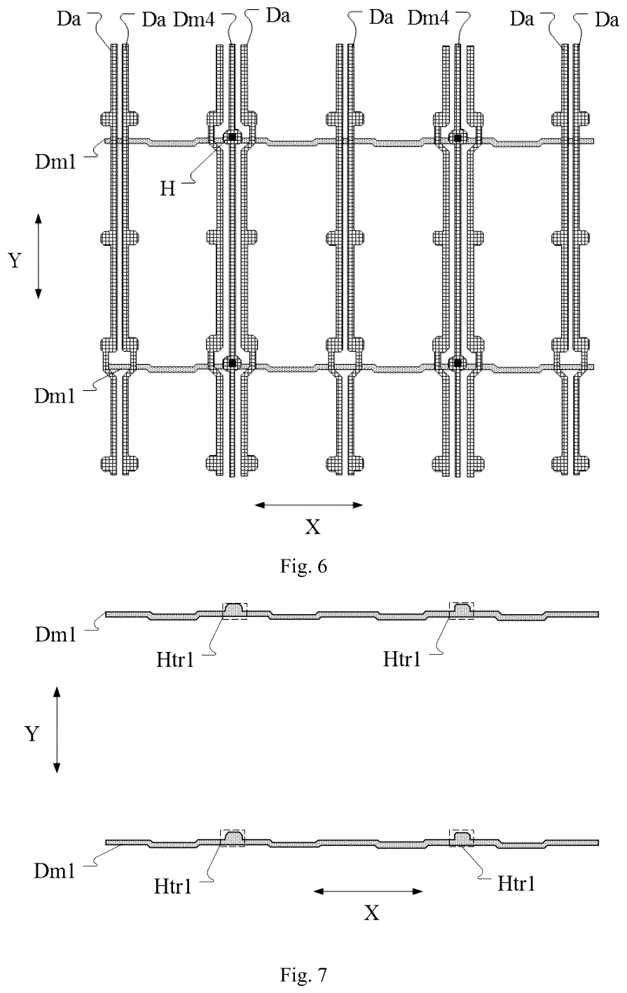

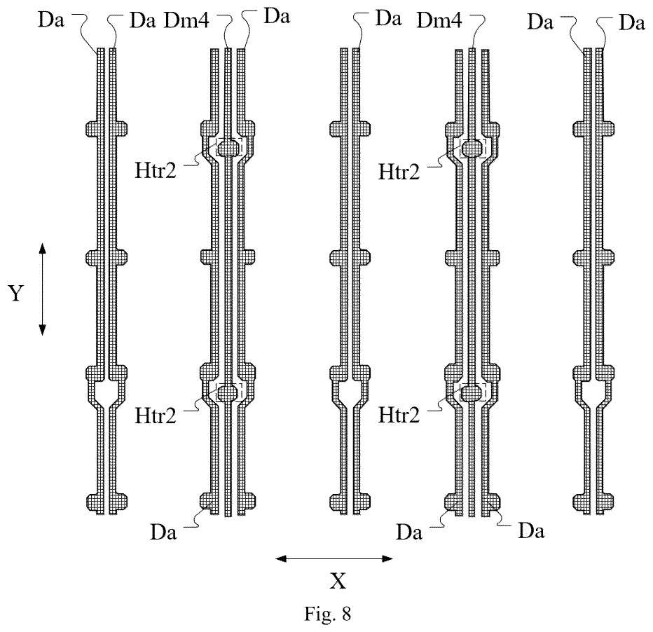

As shown in FIGS. 6, 7, and 8, FIG. 6 is a partially enlarged view of the second area K2 in FIG. 2, FIG. 7 is a partial structural layout of the conductive layer where the first signal line is located in FIG. 6, and FIG. 8 is a partial structural layout of the conductive layer where the second signal line is located in FIG. 6. The second area K2 is located in the display area where the first fan-out sub-area FT11 is away from the second fan-out area FT2. As shown in FIGS. 2 and 6-8, in the second area K2, the fourth simulation line Dm4 is connected through the via hole H to the first simulation line Dm1 that intersects the orthographic projection of the fourth simulation line Dm4 on the base substrate. The black square in FIG. 6 indicates the location of the via hole. In addition, the display area where the second fan-out sub-area FT12 is away from the second fan-out area FT2 may have the same structure as the second area K2.

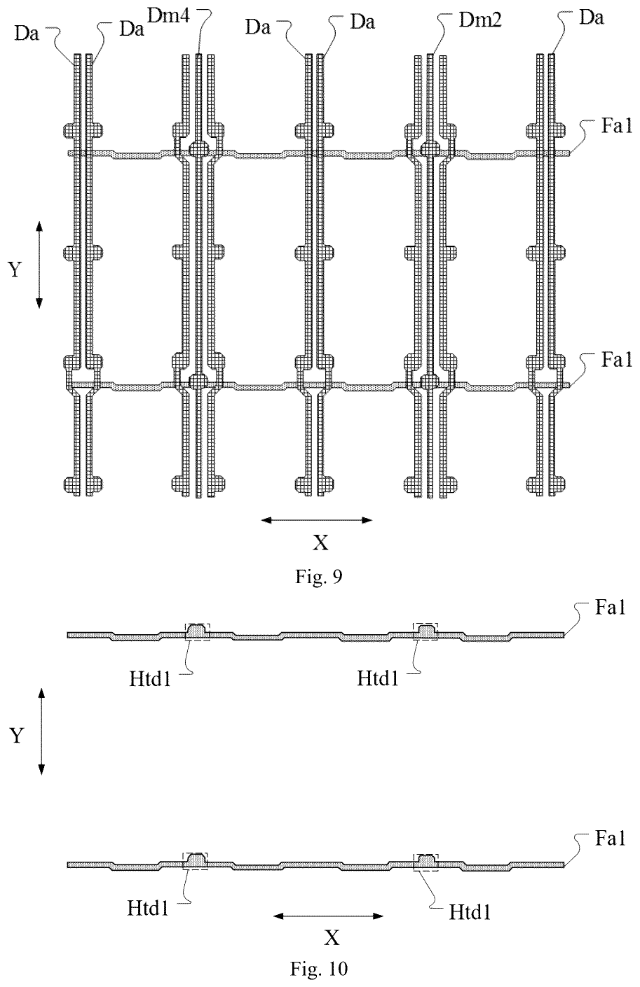

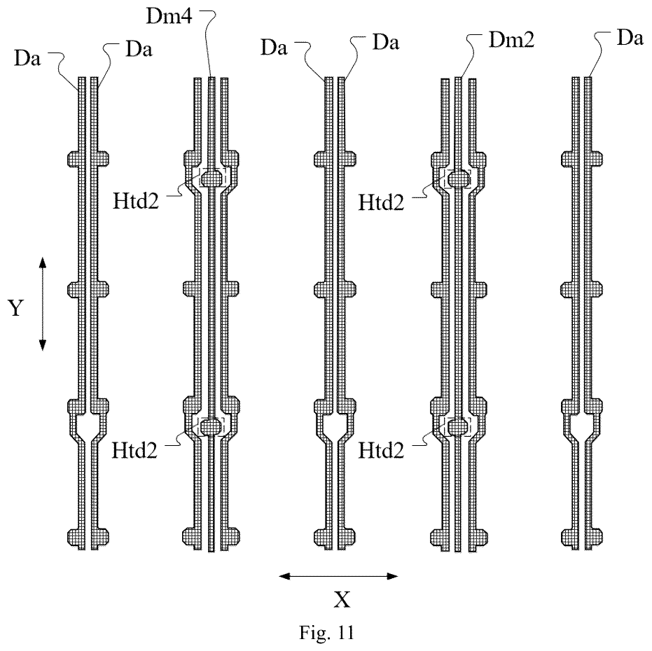

As shown in FIGS. 9, 10, and 11, FIG. 9 is a partially enlarged view of the third area K3 in FIG. 2, FIG. 10 is a partial structural layout of the conductive layer where the first signal line is located in FIG. 9, and FIG. 11 is a partial structural layout of the conductive layer where the second signal line is located in FIG. 9. The third area K3 is located in the first fan-out sub-area FT11. As shown in FIGS. 2 and 9-11, the first data fan-out line Fa1 is not connected to the second simulation line Dm2 and the fourth simulation line Dm4 that intersect the orthographic projection of the first data fan-out line Fa1 on the base substrate. The structures of the first fan-out sub-area FT11 and the second fan-out sub-area FT12 may be the same.

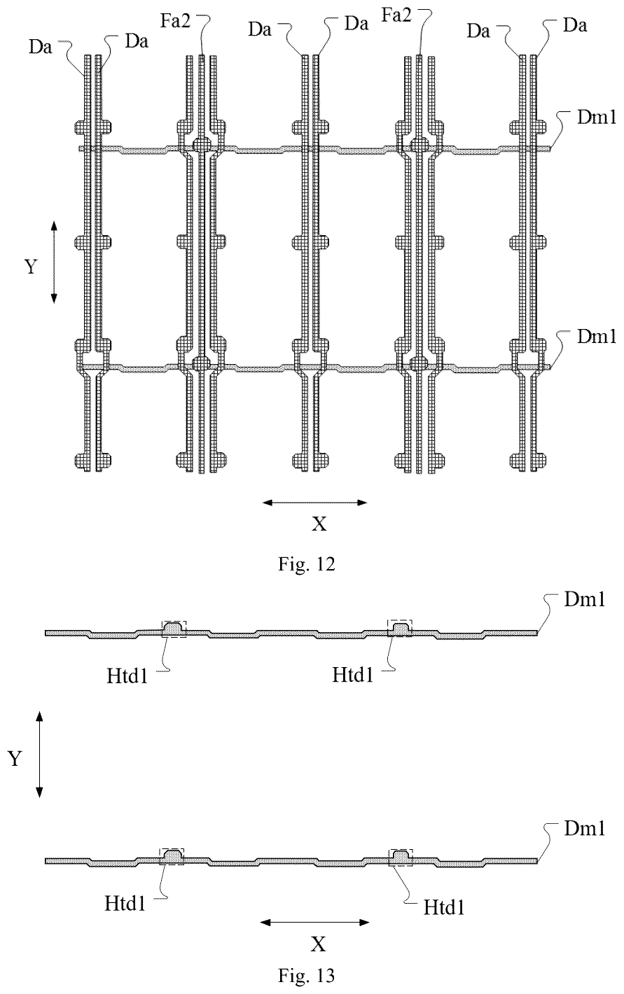

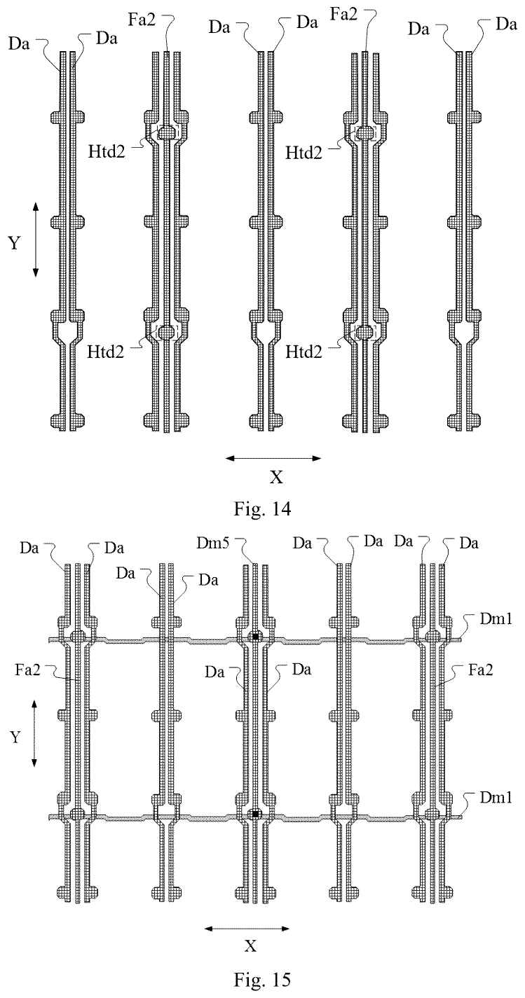

As shown in FIGS. 12, 13, and 14, FIG. 12 is a partial enlarged view of the fourth area K4 in FIG. 2, FIG. 13 is a partial structural layout of the conductive layer where the first signal line is located in FIG. 12, and FIG. 14 is a partial structural layout of the conductive layer where the second signal line is located in FIG. 12. The fourth area K4 is located in the second fan-out area FT2. As shown in FIGS. 2 and 12-14, the second data fan-out line Fa2 is not connected to the first simulation line Dm1 that intersects the orthographic projection of the second data fan-out line Fa2 on the base substrate.

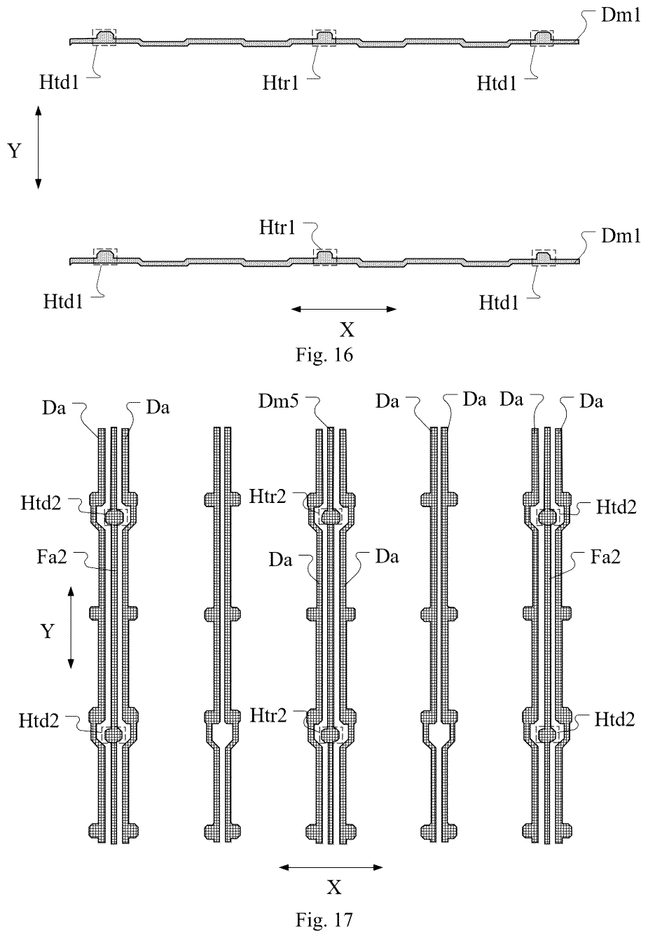

As shown in FIGS. 15, 16, and 17, FIG. 15 is a partially enlarged view of the fifth area K5 in FIG. 2, FIG. 16 is a partial structural layout of the conductive layer where the first signal line is located in FIG. 15, and FIG. 17 is a partial structural layout of the conductive layer where the second signal line is located in FIG. 15. The fifth area K5 is located at the middle position in the first direction X of the second fan-out area FT2. As shown in FIGS. 2 and 15-17, the plurality of second signal lines V2 also includes a fifth simulation line Dm5. A partial structure of the fifth simulation line Dm5 is located in the second fan-out area FT2. The fifth simulation line Dm5 is connected through via holes to the first simulation line Dm1 and the third simulation line Dm3 that intersect the orthographic projection of the fifth simulation line Dm5 on the base substrate. The black square in FIG. 15 indicates the location of the via hole. In an exemplary embodiment, there may be one fifth simulation line. It should be understood that in other exemplary embodiments, there may be a plurality of fifth simulation lines.

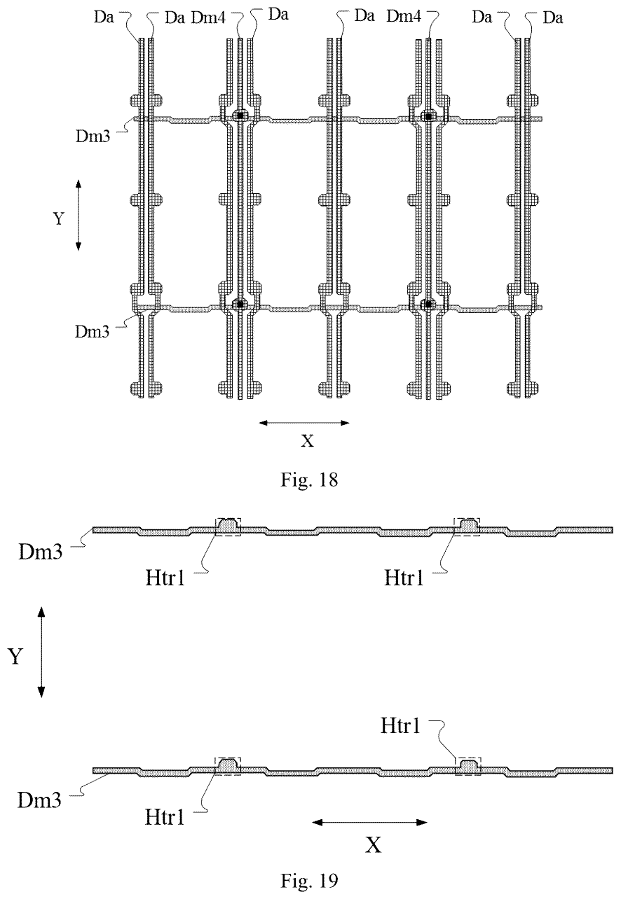

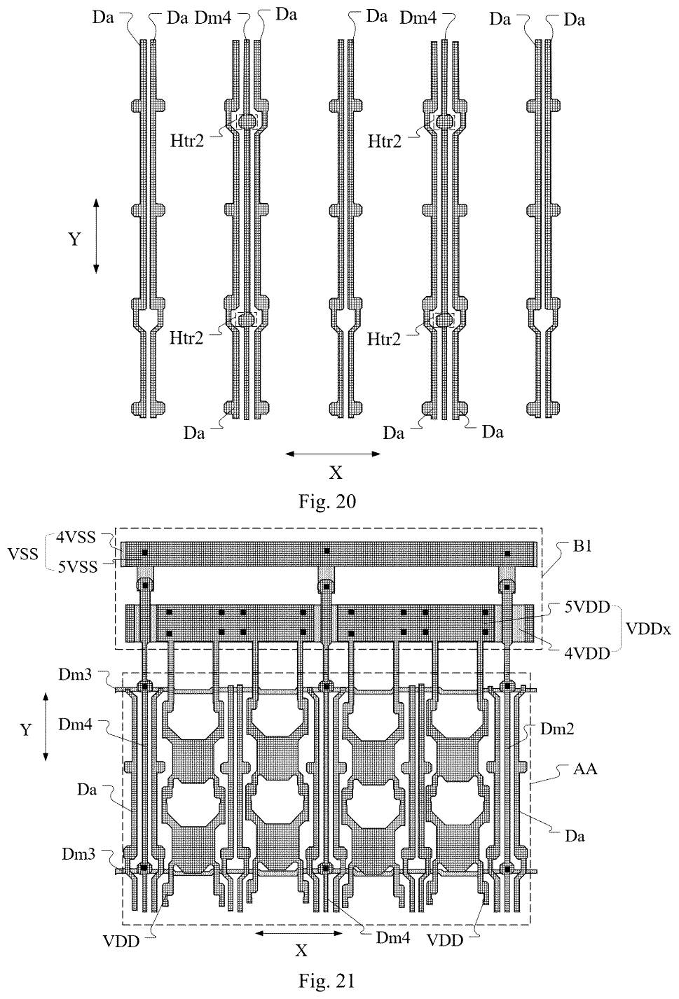

As shown in FIGS. 18, 19, and 20, FIG. 18 is a partial enlarged view of the sixth area K6 in FIG. 2, FIG. 19 is a partial structural layout of the conductive layer where the first signal line is located in FIG. 18, and FIG. 20 is a partial structural layout of the conductive layer where the second signal line is located in FIG. 18. The sixth area K6 is located in the display area at the side of the fan-out area away from the lower frame of the display panel. As shown in FIGS. 2 and 18-20, in the sixth area K6, the third simulation line Dm3 is connected through a via hole to the fourth simulation line Dm4 that intersects the orthographic projection of the third simulation line Dm3 on the base substrate. The black square in FIG. 18 represents the location of the via hole.

In an exemplary embodiment, as shown in FIGS. 2-20, the minimum distance in the second direction Y between the orthographic projections of two adjacent first signal lines H1 on the base substrate is S1. The maximum distance in the second direction Y between the orthographic projections of two adjacent first signal lines H1 on the base substrate is S2. (S2-S1)/S1 may be greater than or equal to 0 and less than or equal to 0.2. For example, (S2-S1)/S1 may be equal to 0, 0.05, 0.1, 0.2, etc. When (S2-S1)/S1 is equal to 0, that is, the orthographic projections of the first signal lines H1 on the base substrate are equally spaced in the second direction Y. As shown in FIGS. 2-20, the minimum distance in the first direction X between the orthographic projections of two adjacent second signal lines V2 on the base substrate is S3. The maximum distance in the first direction X between the orthographic projections of two adjacent second signal lines V2 on the base substrate is S4. (S4-S3)/S3 is greater than or equal to 0 and less than or equal to 0.2. For example, (S4-S3)/S3 may be equal to 0, 0.05, 0.1, 0.2, etc. When (S4-S3)/S3 is equal to 0, that is, the orthographic projections of the second signal lines V2 on the base substrate are equally spaced in the first direction X. This arrangement makes the first signal lines H1 and the second signal lines V2 to be evenly arranged in the display area, thereby further eliminating the above-mentioned problem of dark shadow.

In an exemplary embodiment, the display panel may further include a pixel driving circuit and a light-emitting unit. The pixel driving circuit is connected to the first electrode of the light-emitting unit. The display panel may further include a common electrode layer used to form a second electrode of the light-emitting unit. The first simulation line Dm1, the second simulation line Dm2, the third simulation line Dm3, and the fourth simulation line Dm4 may be connected to the common electrode layer. For example, the first simulation line Dm1, the second simulation line Dm2, the third simulation line Dm3, and the fourth simulation line Dm4 may be connected to the common electrode layer through via holes located in the frame area around the display area. The first simulation line Dm1, the second simulation line Dm2, the third simulation line Dm3, and the fourth simulation line Dm4 forming a grid structure help to reduce the resistance of the common electrode layer itself, thereby reducing the voltage difference on the second electrode of the light-emitting unit at different positions of the display panel. This arrangement helps to improve the display uniformity of the display panel.

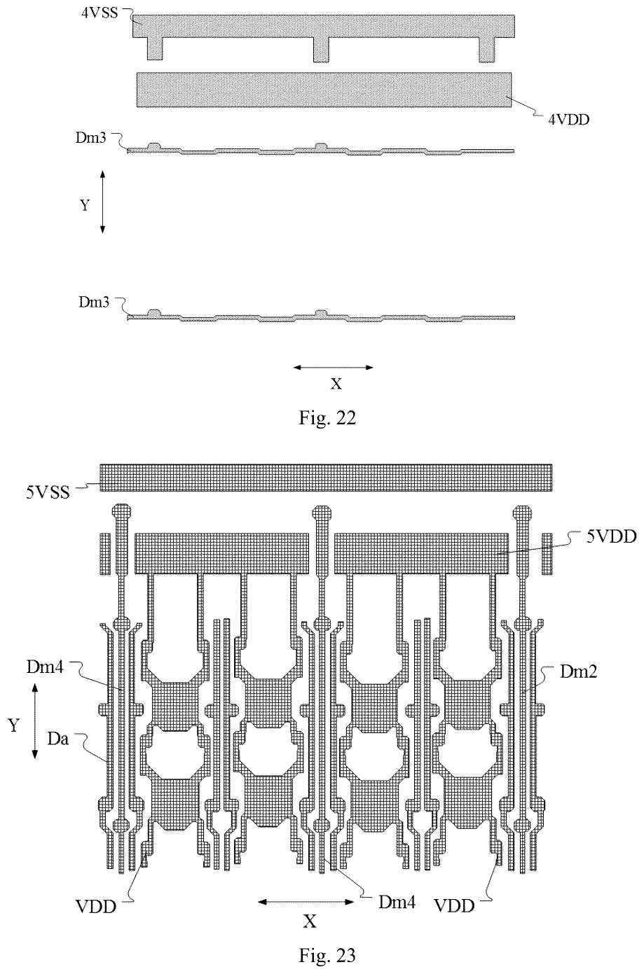

As shown in FIGS. 21-23, FIG. 21 is a partially enlarged view of the seventh area K7 in FIG. 2, FIG. 22 is a structural layout of the conductive layer where the first signal line is located in FIG. 21, and FIG. 23 is a structural layout of the conductive layer where the second signal line is located in FIG. 21. As shown in FIG. 2, the display panel may further include a frame area BB located around the display area AA. The frame area BB includes a first frame area BB1 and a second frame area BB2 arranged oppositely. The fan-out area FT is located on the side close to the second frame area BB2. The display panel may also include an electrode ring VSS and a power circuit (not shown). The electrode ring VSS is located in the frame area BB. The electrode ring VSS may be a ring-shaped structure located in the frame area BB. The electrode ring VSS may be connected to the common electrode layer at different positions. The partial structure of the electrode ring VSS located in the first frame area BB1 is connected to the second simulation line Dm2 and the fourth simulation line Dm4. The power circuit may be bound to the second frame area BB2. The power circuit is connected to at least a partial structure of the electrode ring VSS located in the second frame area BB2. The power circuit may be used to provide a power signal to the electrode ring VSS. The common electrode layer on the side away from the power circuit has a large voltage drop. According to the present application, a power voltage is provided to the second simulation line Dm2 and the fourth simulation line Fm4 through the electrode ring VSS located in the first frame area BB1, thereby reducing the voltage drop of the common electrode layer in the second direction Y.

As shown in FIGS. 21-23, the electrode ring VSS may include a first electrode ring 4VSS and a second electrode ring 5VSS. The orthographic projection of the first electrode ring 4VSS on the base substrate at least partially overlaps with the orthographic projection of the second electrode ring 5VSS on the base substrate. The second electrode ring 5VSS is connected to the first electrode ring 4VSS through a via hole. The black square in FIG. 21 indicates the location of the via hole. The electrode ring with a double-layer conductive structure can reduce the resistance of the electrode ring itself. A power connection line VDDx may also be provided in the first frame area B1. The power connection line VDDx may include a first power connection line 4VDD and a second power connection line 5VDD. The orthographic projections of the first power connection line 4VDD and the second power connection line 5VDD on the base substrate at least partially overlap. The first power connection line 4VDD and the second power connection line 5VDD are connected through a via hole. The power connection line VDDx may be connected to the power line VDD located in the display area.

In an exemplary embodiment, as shown in FIGS. 2-20, the first signal line H1 may include a plurality of first via contact portions Ht1 and a first extension portion Lt1. The orthographic projections of the plurality of first via contact portions Ht1 on the base substrate are arranged at intervals along the first direction X. The first extension portion Lt1 is connected to the first via contact portion Ht1. The dimension in the second direction Y of the orthographic projection of the first via contact portion Ht1 on the base substrate is larger than the dimension in the second direction Y of the orthographic projection of the first extension portion Lt1 on the base substrate. The second signal line V2 may include a plurality of second via contact portions Ht2 and a second extension portion Lt2. The orthographic projections of the plurality of second via contact portions Ht2 on the base substrate are arranged at intervals in the second direction Y. The second extension portion Lt2 is connected to the second via contact portion Ht2. The orthographic projection of the second via contact portion Ht2 on the base substrate has a dimension in the first direction X, which is larger than the dimension in the first direction X of the orthographic projection of the second extension portion Lt2 on the base substrate. The first via contact portion Ht1 is arranged correspondingly to a respective second via contact portion Ht2. The orthographic projection of the first via contact portion Ht1 on the base substrate at least partially overlaps with the orthographic projection of the respective second via contact portion Ht2 on the base substrate.

As shown in FIGS. 2-20, the first via contact portion Ht1 may include a first real hole contact portion Htr1 and a first dummy hole contact portion Htd1. The second via contact portion Ht2 may include a second real hole contact portion Htr2 and a second dummy hole contact portion Htd2. The first real hole contact portion Htr1 and the respective second real hole contact portion Htr2 are connected through a via hole. That is, the first signal line H1 and the second signal line V2 may be connected through via holes by means of the first real hole contact portion Htr1 and the second real hole contact portion Htr2. The first dummy hole contact portion Htd1 and the respective second dummy hole contact portion Htd2 are insulated. The first dummy hole contact portion Htd1 may simulate the light-reflecting phenomenon of the first real hole contact portion Htr1, and the second dummy hole contact portion Htd2 may simulate the light-reflecting phenomenon of the second real hole contact portion Htr2. Therefore, the first dummy hole contact portion Htd1 and the second dummy hole contact portion Htd2 can improve the dark shadow problem of the display panel in the screen-off state. In addition, the first dummy hole contact portion Htd1 may simulate the parasitic capacitance of the first real hole contact portion Htr1, and the second dummy hole contact portion Htd2 may simulate the parasitic capacitance of the second real hole contact portion Htr2. Thus, the first dummy hole contact portion Htd1 and the second dummy hole contact portion Htd2 can improve the display uniformity of the display panel.

In an exemplary embodiment, the orthographic projections of the first dummy hole contact portion Htd1 and the second dummy hole contact portion Htd2 on the base substrate overlap with each other. Therefore, from the perspective of light reflection, the display panel may be provided with either the first dummy hole contact portion Htd1 or the second dummy hole contact portion Htd2.

In an exemplary embodiment, as shown in FIGS. 2-20, the minimum distance in the first direction X between the orthographic projections of adjacent first via contact portions Ht1 on the base substrate is S5. The maximum distance in the first direction X between the orthographic projections of adjacent first via contact portions Ht1 on the base substrate is S6. (S6−S5)/S5 may be larger than or equal to 0 and less than or equal to 0.2. For example, (S6−S5)/S5 may be equal to 0, 0.05, 0.1, 0.2, etc. When (S6−S5)/S5 is equal to 0, the orthographic projections of the first via contact portions Ht1 on the base substrate are equally spaced in the first direction X. The first via contact portions Ht1 arranged at equal intervals can further improve the dark shadow problem of the display panel in the screen-off state. As shown in FIGS. 2-20, the minimum distance in the second direction Y between the orthographic projections of adjacent second via contact portions Ht2 on the base substrate is S7. The maximum distance in the second direction Y between the orthographic projections of adjacent second via contact portions Ht2 on the base substrate is S8. (S8−S7)/S7 is greater than or equal to 0 and less than or equal to 0.2. For example, (S8−S7)/S7 may be equal to 0, 0.05, 0.1, 0.2, etc. When (S8−S7)/S7 is equal to 0, the orthographic projections of the second via contact portions Ht2 on the base substrate are equally spaced in the second direction Y. The equally spaced second via contact portions Ht2 can further improve the dark shadow problem of the display panel in the screen-off state.

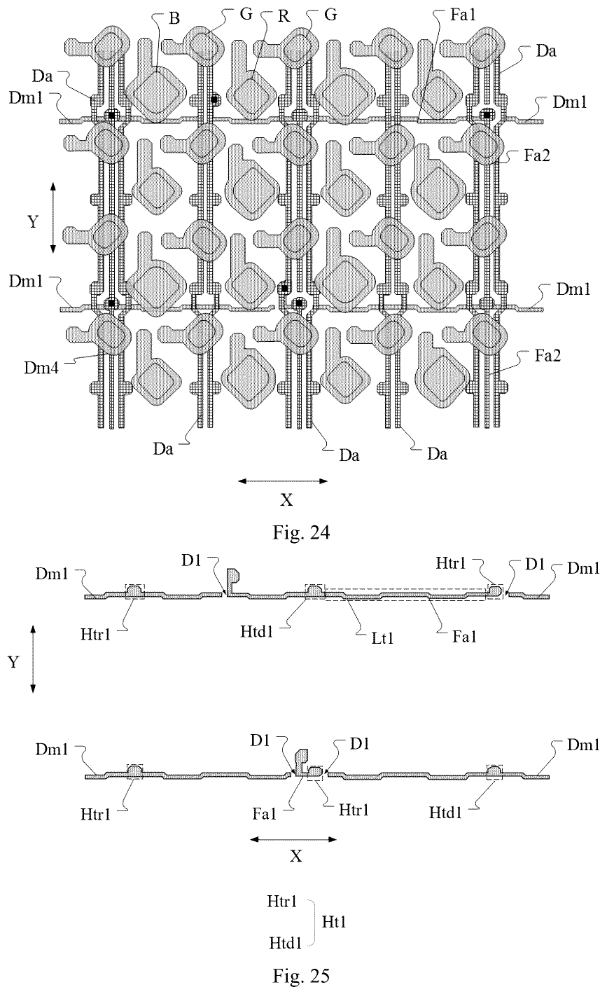

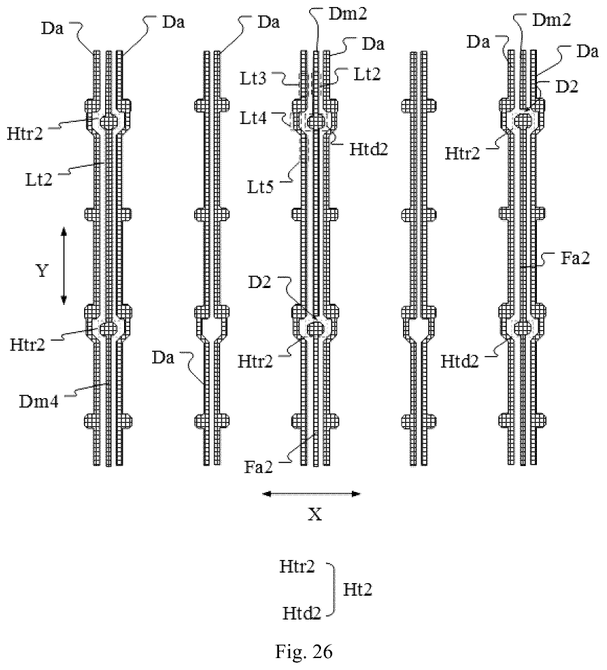

In an exemplary embodiment, the display panel further includes a pixel driving circuit and a light-emitting unit. The pixel driving circuit is connected to the first electrode of the light-emitting unit. The display panel further includes an electrode layer used to form the first electrode of the light-emitting unit. As shown in FIGS. 24, 25, 26, and 27, FIG. 24 is a structural layout of the display panel according to another exemplary embodiment of the present disclosure, FIG. 25 is a structural layout of the conductive layer where the first signal line is located in FIG. 24. FIG. 26 is a structural layout of the conductive layer where the second signal line is located in FIG. 24, and FIG. 27 is a structural layout of the electrode layer in FIG. 24. The electrode layer may include a plurality of electrode portions. The plurality of electrode portions includes a first electrode portion R, a second electrode portion B, and a third electrode portion G. The first electrode portion R may be used to form the first electrode of the red light-emitting unit. The second electrode portion B may be used to form the first electrode of the blue light-emitting unit. The third electrode portion G may be used to form the first electrode of the green light-emitting unit. The display panel further includes a pixel definition layer located on a side of the electrode layer away from the base substrate. The pixel opening used for forming a light-emitting unit is formed on the pixel definition layer. The orthographic projection on the base substrate of the first electrode portion R coincides with the orthographic projection on the base substrate of the respective pixel opening on the pixel definition layer. The orthographic projection of the third electrode portion G on the base substrate coincides with the orthographic projection of the respective pixel opening on the base substrate. The orthographic projection of the second electrode portion B on the base substrate coincides with the orthographic projection of the respective pixel opening on the base substrate.

As shown in FIGS. 24-27, the orthographic projection of the notch D1 between the first data fan-out line Fa1 and the first simulation line Dm1 on the base substrate does not overlap with the orthographic projection of the electrode portion on the base substrate. The orthographic projection of the notch D2 between the second data fan-out line Fa2 and the second simulation line Dm2 on the base substrate does not overlap with the orthographic projection of the electrode portion on the base substrate. This arrangement can improve the flatness of the electrode portion, and a light-emitting material layer with higher flatness can be formed on the electrode portion with higher flatness, thereby improving the display uniformity of the display panel.

In an exemplary embodiment, the first real hole contact portion Htr1 and the second real hole contact portion Htr2 are connected through a via hole. The second real hole contact portion Htr2 is recessed towards the base substrate at the position of the via hole. The second real hole contact portion Htr2 will have a strong light reflection phenomenon at the recessed position. However, the first dummy hole contact portion Htd1 and the second dummy hole contact portion Htd2 are not connected, the second dummy hole contact portion Htd2 is relatively flat, and the second dummy hole contact portion Htd2 has a weak light reflection effect. The inconsistent light reflection capabilities of the second dummy hole contact portion Htd2 and the second real hole contact portion Htr2 may easily cause a dark shadow to appear on the display panel in the screen-off state.

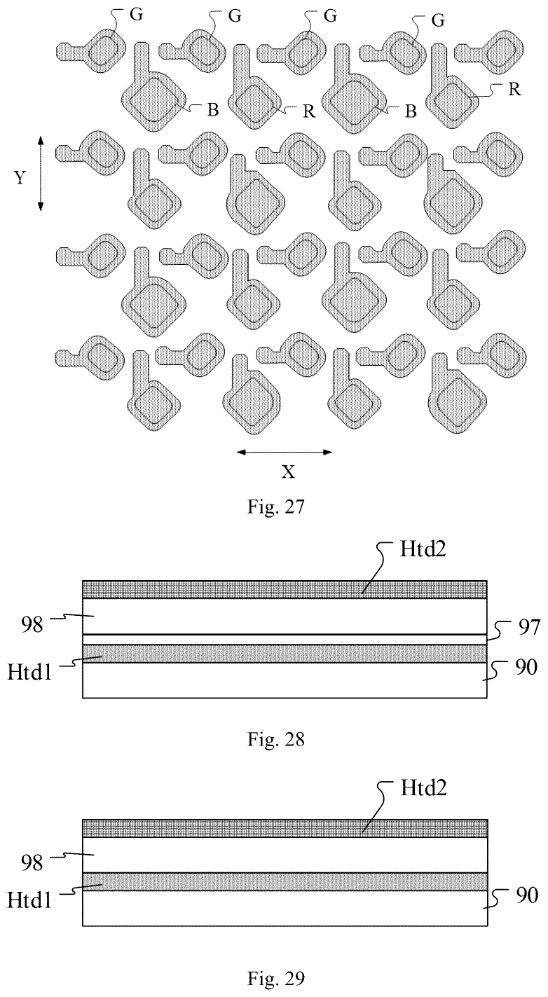

As shown in FIG. 28, it is a partial cross-sectional view of the display panel shown in FIG. 3 along the dotted line CC. The first signal line is located on the first source-drain layer, and the second signal line is located on the second source-drain layer. The display panel may also include a first planarization layer 98 and a passivation layer 97 located on one side of the base substrate 90. The passivation layer 97 is located between the first source-drain layer and the second source-drain layer. The first planarization layer 98 is located between the passivation layer 97 and the second source-drain layer. The thickness of the first planarization layer 98 is much greater than the thickness of the passivation layer 97. In an exemplary embodiment, the depth of the recess of the second real hole contact portion Htr2 at the via hole position can be reduced by reducing the thickness of the passivation layer 97 and/or the first planarization layer 98, thereby improving the above mentioned problem of dark shadow. In an exemplary embodiment, the thickness of the first planarization layer 98 may be less than or equal to 1.6 μm. For example, the thickness of the first planarization layer 98 may be 1.2 μm, 1.3 μm, 1.4 μm, 1.5 μm, or 1.6 μm. The thickness of the passivation layer 97 may be 1000 angstroms to 5000 angstroms. For example, the thickness of the passivation layer 97 may be 1000 angstroms, 2000 angstroms, 3000 angstroms, 4000 angstroms, or 5000 angstroms.

As shown in FIG. 29, it is a schematic structural diagram of a display panel according to another exemplary embodiment of the present disclosure. Only the first planarization layer 98 is provided between the first source-drain layer and the second source-drain layer in this display panel. This arrangement can also reduce the depth of the recess of the second real hole contact portion Htr2 at the via hole position, thereby improving the aforementioned issue of dark shadow.

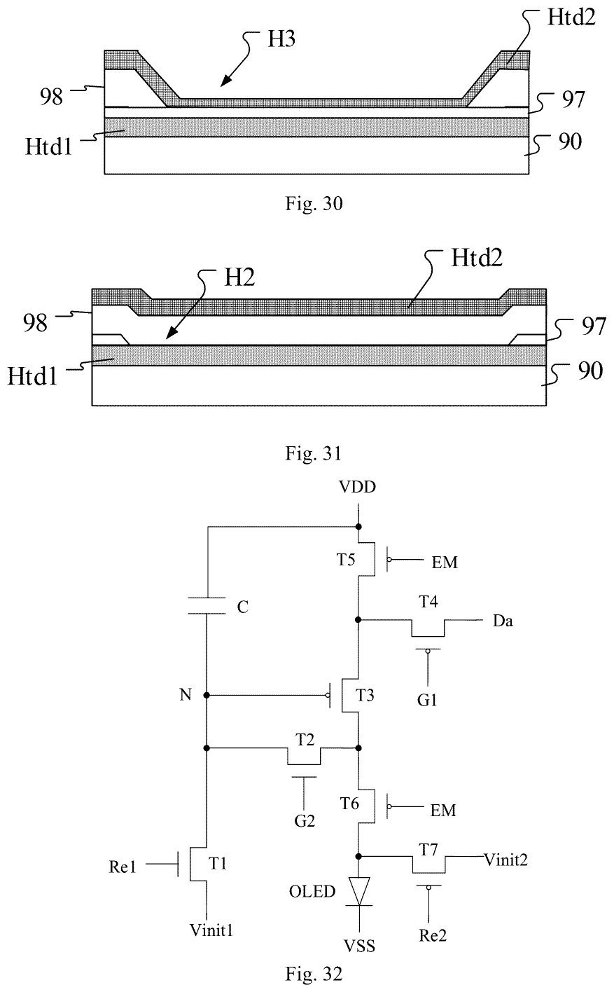

As shown in FIG. 30, it is a schematic structural diagram of a display panel according to another exemplary embodiment of the present disclosure. In this exemplary embodiment, a first opening H3 is formed on the first planarization layer 98. The orthographic projection of the first opening H3 on the base substrate at least partially overlaps with the orthographic projection of the second dummy hole contact portion Htd2 on the base substrate. This arrangement allows the second dummy hole contact portion Htd2 to form a groove facing the base substrate 90, thereby improving the uniformity of light reflection in the display area by increasing the light reflection capability of the second dummy hole contact portion Htd2. The first opening H3 may be an opening that penetrates the first planarization layer 98, or a blind hole that does not penetrate the first planarization layer 98.

As shown in FIG. 31, it is a schematic structural diagram of a display panel according to another exemplary embodiment of the present disclosure. In this exemplary embodiment, a second opening H2 is formed on the passivation layer 97. The orthographic projection of the second opening H2 on the base substrate at least partially overlaps with the orthographic projection of the second dummy hole contact portion Htd2 on the base substrate. This arrangement allows the second dummy hole contact portion Htd2 to form a recessed groove facing the base substrate 90, thereby improving the uniformity of light reflection in the display area by increasing the light reflection capability of the second dummy hole contact portion Htd2. The second opening H2 may be an opening that penetrates the passivation layer 97, or a blind hole that does not penetrate the passivation layer 97.

In an exemplary embodiment, since the orthographic projections of the first via contact portion Ht1 and the second via contact portion Ht2 on the base substrate overlap with each other, the second via contact portion Ht2 has a higher protrusion than other positions. At the same time, since the local area of the second real hole contact portion Htr2 has a groove, in order to improve the flatness of the electrode portion, as shown in FIG. 24, in an exemplary embodiment, the orthographic projection of the first via contact portion Ht1 on the base substrate does not overlap with the orthographic projection of the electrode portion on the base substrate, and the orthographic projection of the second via contact portion Ht2 on the base substrate does not overlap with the orthographic projection of the electrode portion on the base substrate.

As shown in FIG. 26, among the data lines Da located on adjacent sides of the second signal line V2, the data line Da includes a third extension portion Lt3, a fourth extension portion Lt4, and a fifth extension portion Lt5. The fourth extension portion Lt4 is connected between the third extension portion Lt3 and the fifth extension portion Lt5. The data lines Da located on adjacent sides of the second signal line V2 refer to those data lines with no other data lines exsiting between them and the second signal line V2. At least partial structures of the second via contact portion Ht2 and the fourth extension portion Lt4 are oppositely arranged in the first direction X. The dimensions in the first direction X of the orthographic projections of the fourth extension portion Lt4 on the base substrate the second extension portion Lt2 on the base substrate are larger than the dimensions in the first direction X of the orthographic projection of the third extension portion Lt3 on the base substrate and the orthographic projection of the second extension portion Lt2 on the base substrate. The dimensions in the first direction X of the orthographic projection of the fourth extension portion Lt4 on the base substrate and the orthographic projection of the second extension portion Lt2 on the base substrate are larger than the dimensions in the first direction X of the orthographic projection of the fifth extension portion Lt5 on the base substrate and the orthographic projection of the second extension portion Lt2 on the base substrate. The structure A and the structure B are arranged oppositely in the first direction. It can be understood that the area covered by the orthographic projection of the structure A on the base substrate being infinitely moved in the first direction coincides with the area covered by the orthographic projection of the structure B on the base substrate being infinitely moved in the first direction. This arrangement allows sufficient installation space for the second via contact portion Ht2.

As shown in FIGS. 24-27, the dimension in the first direction X of the orthographic projection of the notch D1 between the first data fan-out line Fa1 and the first simulation line Dm1 on the base substrate may be 1.5 μm-3.5 μm. For example, the dimension in the first direction X of the orthographic projection of the notch D1 on the base substrate may be 1.5 μm, 2 μm, 2.5 μm, 3 μm, 3.5 μm, etc. The dimension in the second direction Y of the orthographic projection of the notch D2 between the second data fan-out line Fa2 and the second simulation line Dm2 on the base substrate is 1.5 μm-3.5 μm. For example, the dimension in the second direction Y of the orthographic projection of the notch D2 on the base substrate is 1.5 μm, 2 μm, 2.5 μm, 3 μm, 3.5 μm, etc. When the dimension in the first direction X of the orthographic projection of the notch D1 on the base substrate and the dimension in the second direction Y of the orthographic projection of the notch D2 on the base substrate are smaller, there will be no noticeable dark shadows on the display panel.

In an exemplary embodiment, in the same second signal line, the distance in the second direction Y between the orthographic projections on the base substrate of two second via contact portions Ht2 being adjacent in the second direction Y is A1, and the dimension in the second direction Y of the orthographic projection of the notch D2 between the second data fan-out line Fa2 and the second simulation line Dm2 on the base substrate is A2. A1/A2 may be greater than or equal to 27 and less than or equal to 68. For example, A1/A2 may be equal to 27, 28, 29, 35, 40, 54, 50, 55, 60, 65, 66, 67, etc.

As shown in FIG. 32, it is a schematic circuit structure diagram of the pixel driving circuit in the display panel of the present disclosure. The pixel driving circuit may include a driving transistor T3, a first transistor T1, a second transistor T2, a fourth transistor T4, a fifth transistor T5, a sixth transistor T6, a seventh transistor T7, and a capacitor C. The first terminal of the fourth transistor T4 is connected to the data signal terminal Da. The second terminal of the fourth transistor T4 is connected to the first terminal of the driving transistor T3. The gate of the fourth transistor T4 is connected to the first gate driving signal terminal G1. The first terminal of the fifth transistor T5 is connected to the first power terminal VDD. The second terminal of the fifth transistor T5 is connected to the first terminal of the driving transistor T3. The gate of the fifth transistor T5 is connected to the enable signal terminal EM. The gate of the driving transistor T3 is connected to the node N. The first terminal of the second transistor T2 is connected to the node N. The second terminal of the second transistor T2 is connected to the second terminal of the driving transistor T3. The gate of the second transistor T2 is connected to the second gate driving signal terminal G2. The first terminal of the sixth transistor T6 is connected to the second terminal of the driving transistor T3. The second terminal of the sixth transistor T6 is connected to the second terminal of the seventh transistor T7. The gate of the sixth transistor T6 is connected to the enable signal terminal EM. The first terminal of the seventh transistor T7 is connected to the second initial signal terminal Vinit2. The gate of the seventh transistor T7 is connected to the second reset signal terminal Re2. The second terminal of the first transistor T1 is connected to the node N. The first terminal of the first transistor T1 is connected to the first initial signal terminal Vinit1. The gate of the first transistor T1 is connected to the first reset signal terminal Re1. The first electrode of the capacitor C is connected to the node N. The second electrode of the capacitor C is connected to the first power terminal VDD. The pixel driving circuit may be connected to a light-emitting unit OLED. The pixel driving circuit is used to drive the light-emitting unit OLED to emit light. The first electrode of the light-emitting unit OLED may be connected to the second terminal of the sixth transistor T6. The second electrode of the light-emitting unit may be connected to the second power terminal VSS. The first electrode of the light-emitting unit may be the anode of the light-emitting unit, and the second electrode of the light-emitting unit may be the cathode of the light-emitting unit. The first transistor T1 and the second transistor T2 may be N-type transistors. For example, the first transistor T1 and the second transistor T2 may be N-type metal oxide transistors. N-type transistors have smaller leakage current, thereby avoiding that in the light-emitting phase, node N leaks electricity through the first transistor T1 and the second transistor T2. At the same time, the driving transistor T3, the fourth transistor T4, the fifth transistor T5, the sixth transistor T6, and the seventh transistor T7 may be P-type transistors. For example, the driving transistor T3, the fourth transistor T4, the fifth transistor T5, the sixth transistor T6, and the seventh transistor T7 may be P-type low-temperature polycrystalline silicon transistors. P-type transistors have high carrier mobility. This is conducive to achieving a display panel with high resolution, high response speed, high pixel density, or high aperture ratio. The first initial signal terminal and the second initial signal terminal may output the same voltage signal or different voltage signals according to actual conditions.

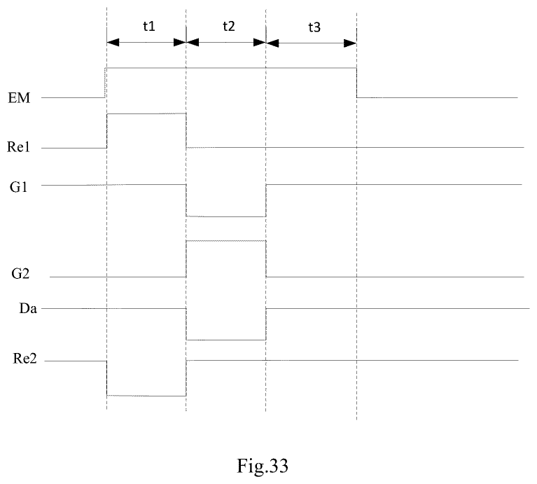

As shown in FIG. 33, it is a timing diagram of each node in a driving method of the pixel driving circuit in FIG. 32. G1 represents the timing of the first gate drive signal terminal G1, G2 represents the timing of the second gate drive signal terminal G2, Re1 represents the timing of the first reset signal terminal Re1, Re2 represents the timing of the second reset signal terminal Re2, EM represents the timing of the enable signal terminal EM, and Da represents the timing of the data signal terminal Da. The driving method of the pixel driving circuit may include a reset phase t1, a data writing phase t2, and a light-emitting phase t3. During the reset phase t1, the first reset signal terminal Re1 outputs a high-level signal, the second reset signal terminal Re2 outputs a low-level signal, the first transistor T1 and the seventh transistor T7 are turned on, the first initial signal terminal Vinit1 inputs the first initial signal to the node N, and the second initial signal terminal Vinit2 inputs the second initial signal to the first electrode of the light-emitting unit OLED. During the data writing stage t2, the second gate drive signal terminal G2 outputs a high-level signal, the first gate drive signal terminal G1 outputs a low-level signal, the fourth transistor T4 and the second transistor T2 are turned on, and at the same time, the data signal terminal Da outputs the data signal to write the compensation voltage Vdata+Vth to the node N, where Vdata is the voltage of the data signal, and Vth is the threshold voltage of the driving transistor T3. During the light-emitting phase t3, the enable signal terminal EM outputs a low-level signal, the sixth transistor T6 and the fifth transistor T5 are turned on, and the driving transistor T3 drives the light-emitting unit to emit light under the effect of the compensation voltage Vdata+Vth stored in the capacitor C.

The output current formula of the driving transistor is as follows:

I=(μWCox/2L)(Vgs−Vth)²

where I is the output current of the driving transistor, u is the carrier mobility, Cox is the gate capacitance per unit area, W is the channel width of the driving transistor, L is the channel length of the driving transistor, Vgs is the gate-source voltage difference of the driving transistor, and Vth is the threshold voltage of the driving transistor. The output current of the driving transistor in the pixel driving circuit of the present disclosure is I=(μWCox/2L) (Vdata+Vth−Vdd−Vth)². The pixel driving circuit can avoid the influence of the threshold of the driving transistor on the output current of the driving transistor. It should be understood that in other exemplary embodiments, the pixel driving circuit may also have other driving methods. For example, the seventh transistor T7 may reset the first electrode of the light-emitting unit during a period between the data writing stage t2 and the light-emitting stage t3.

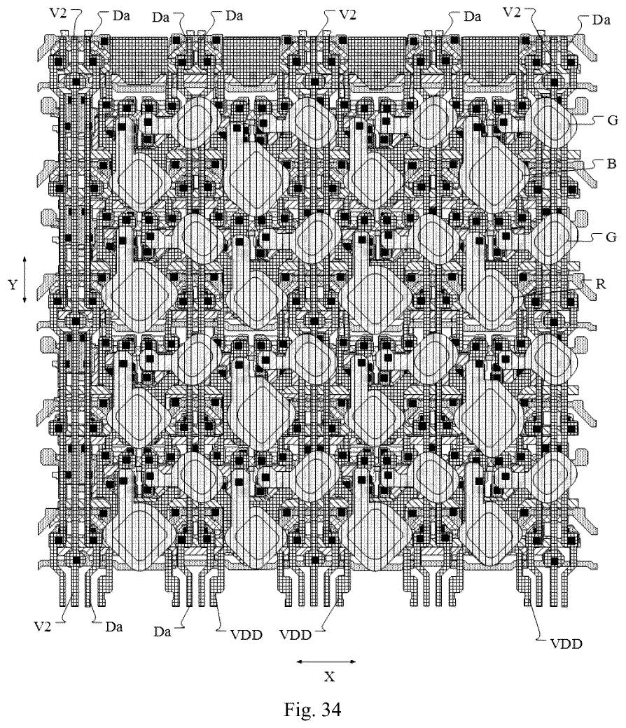

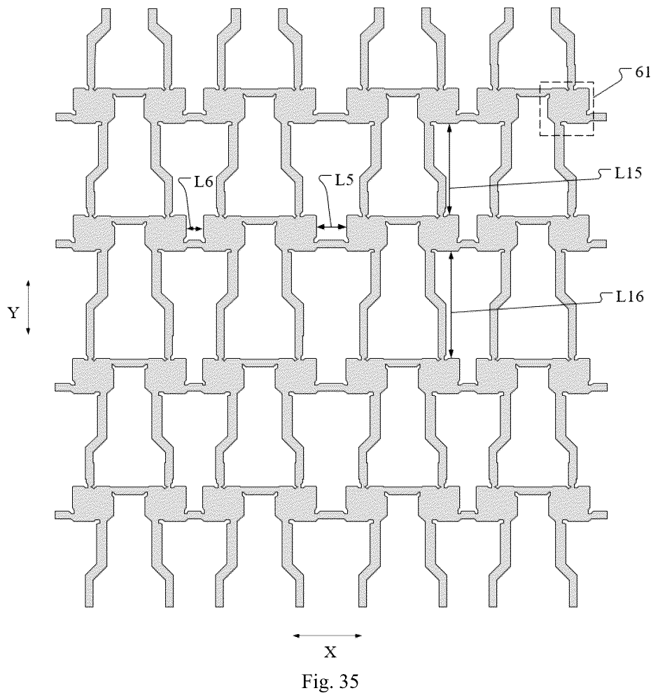

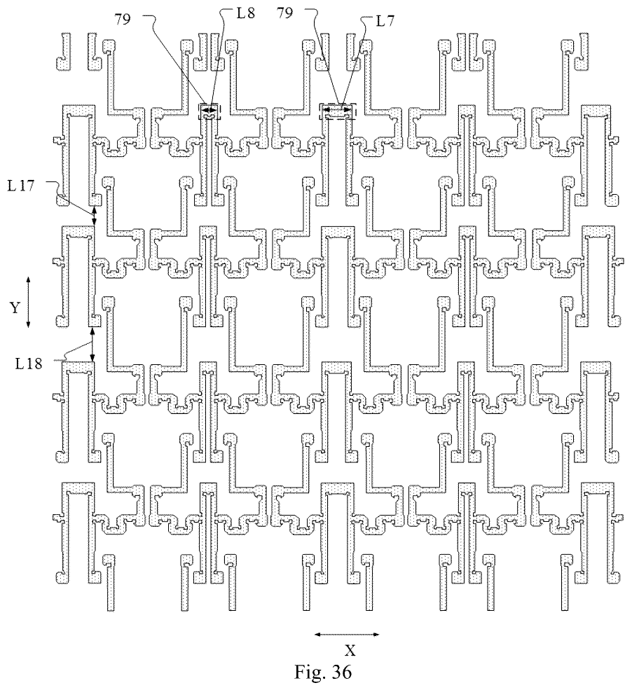

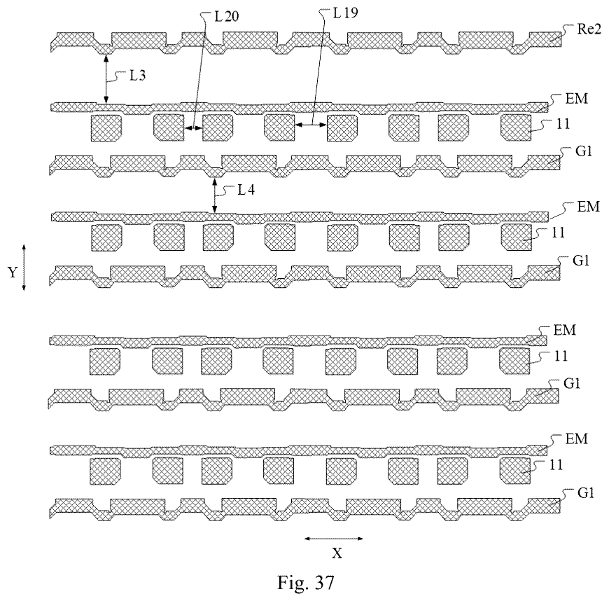

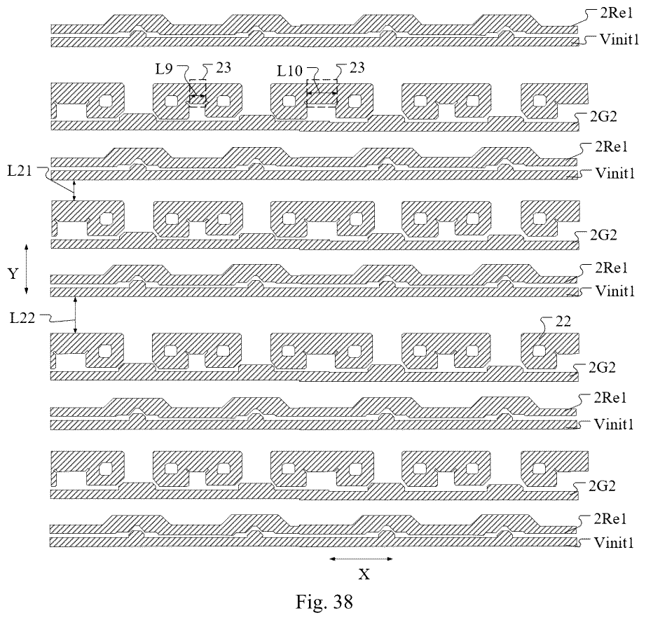

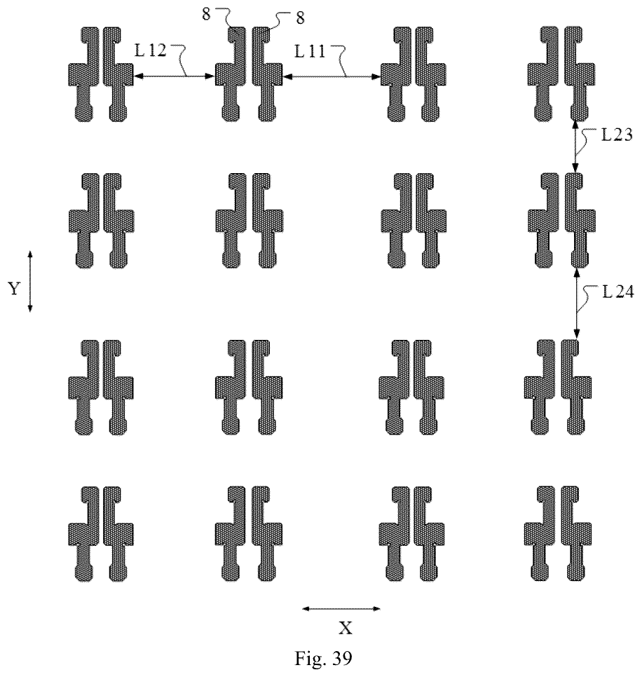

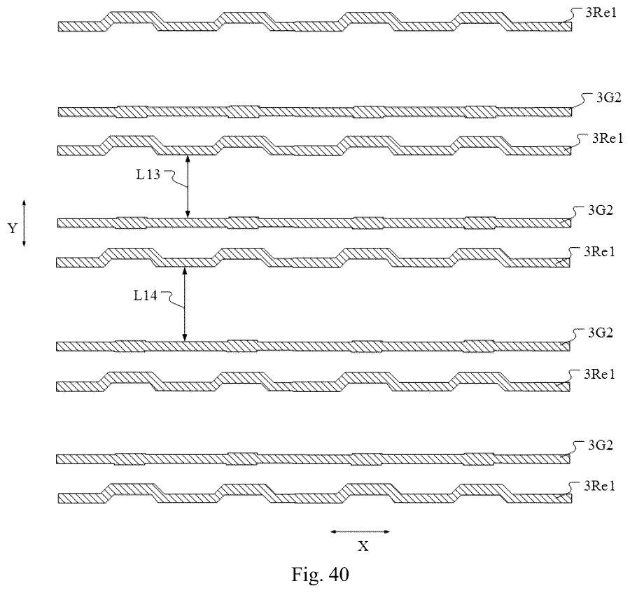

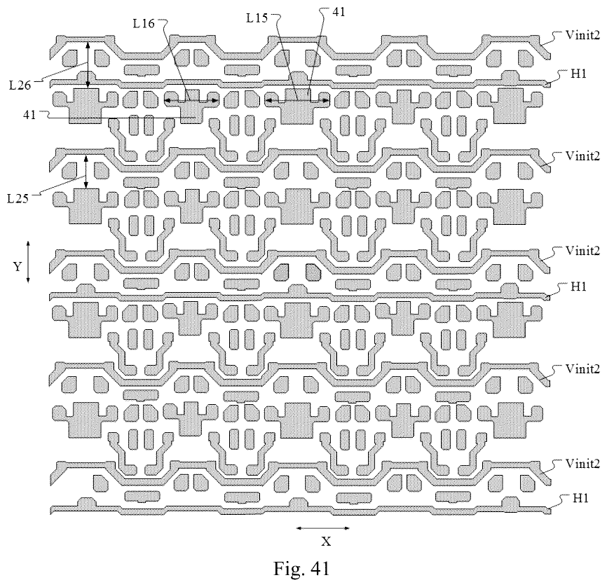

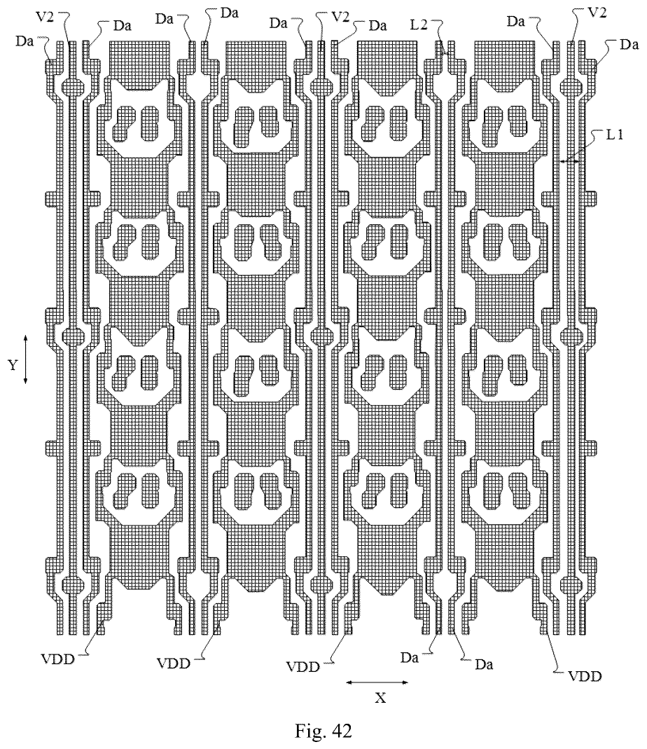

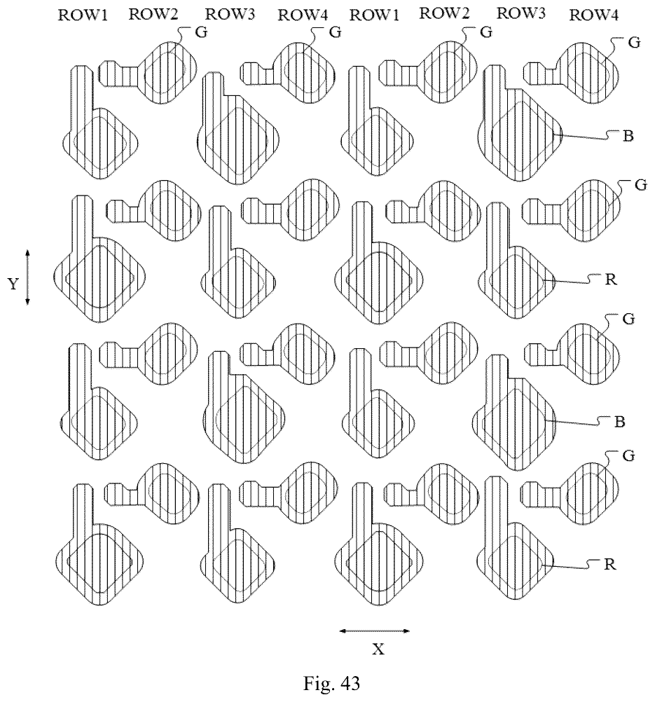

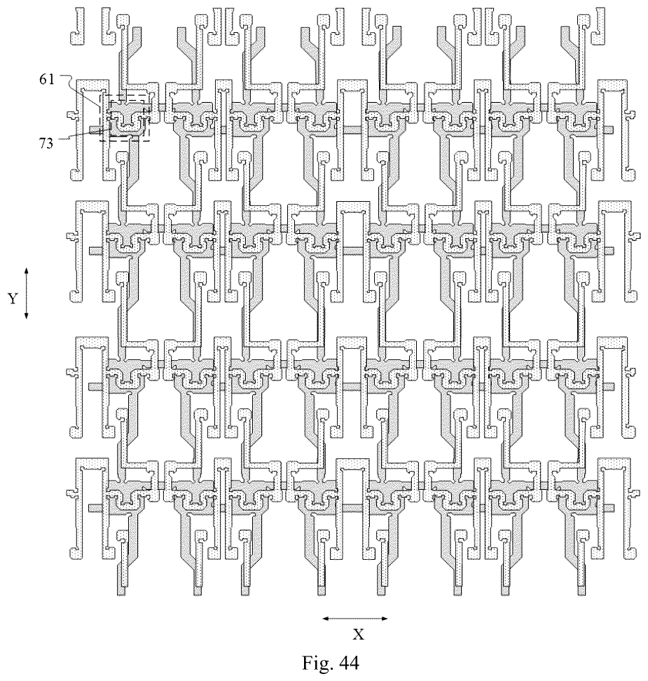

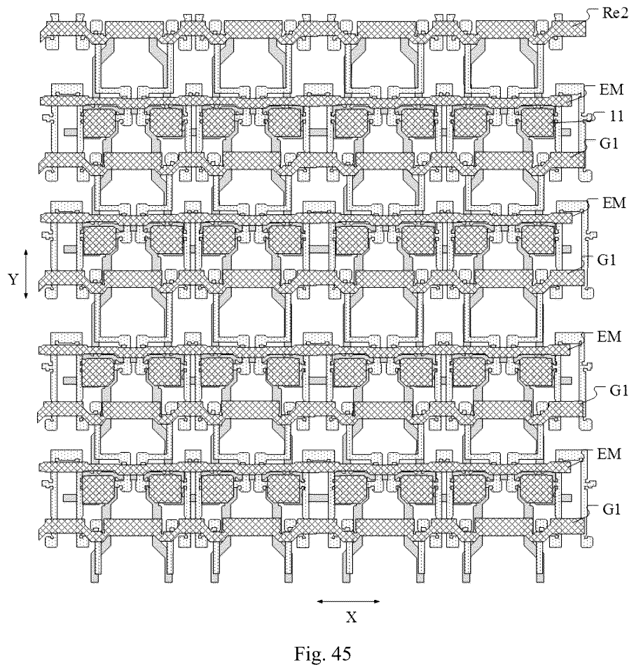

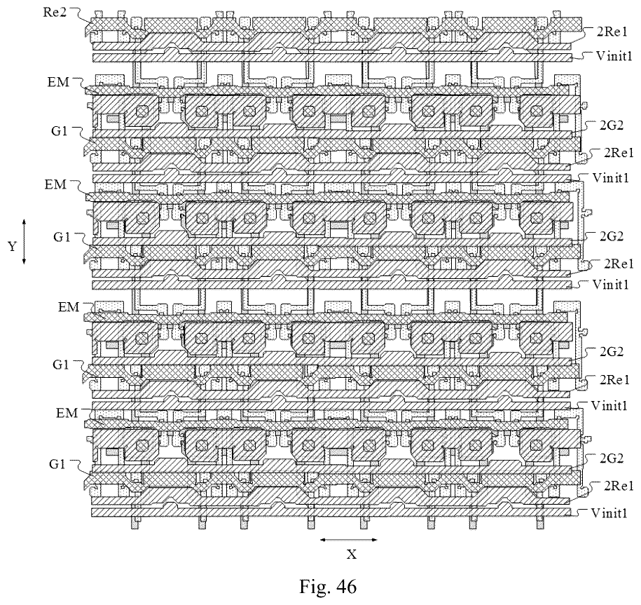

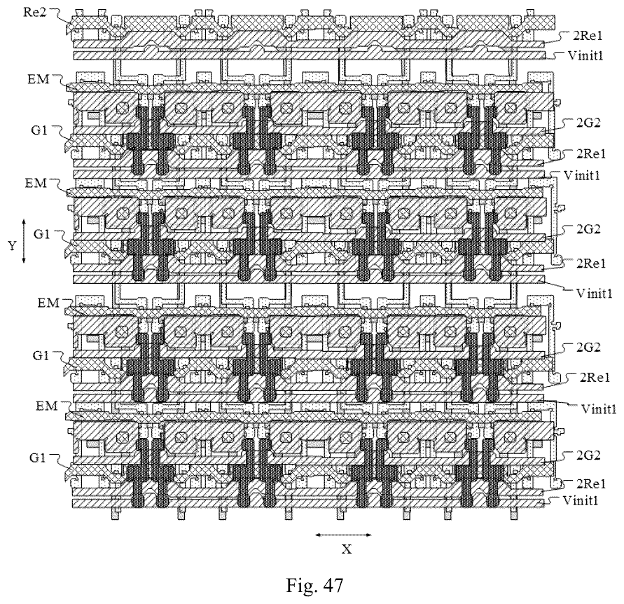

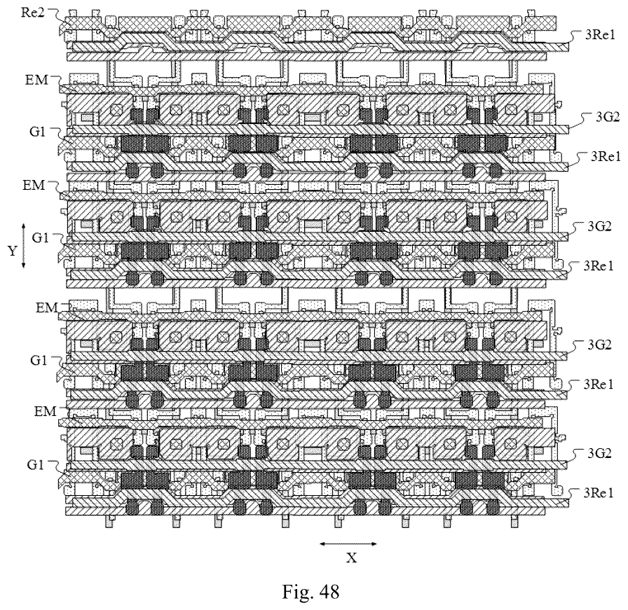

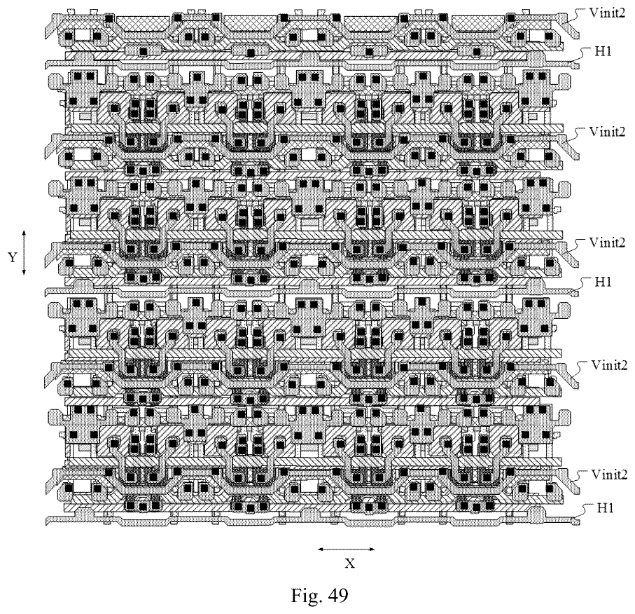

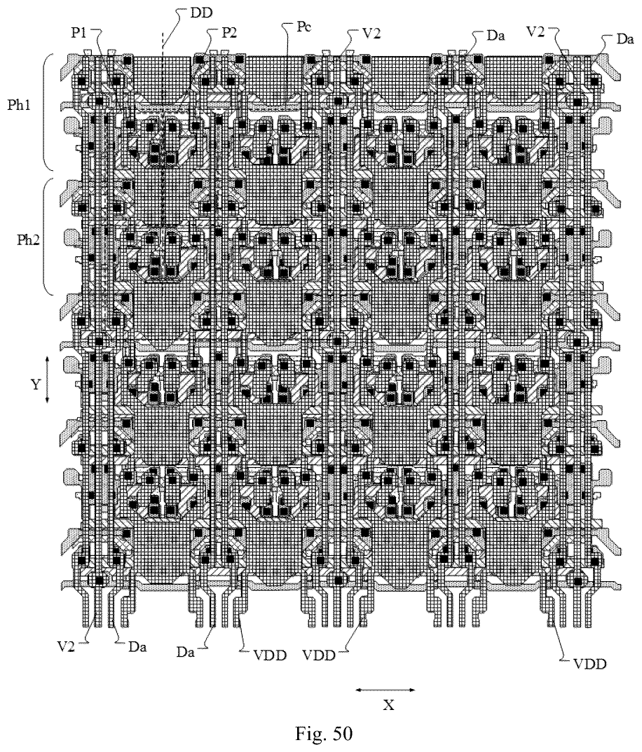

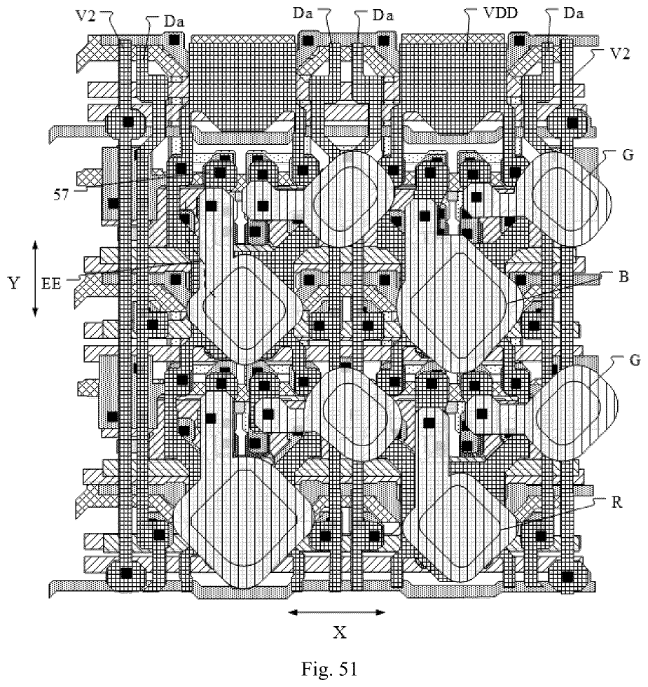

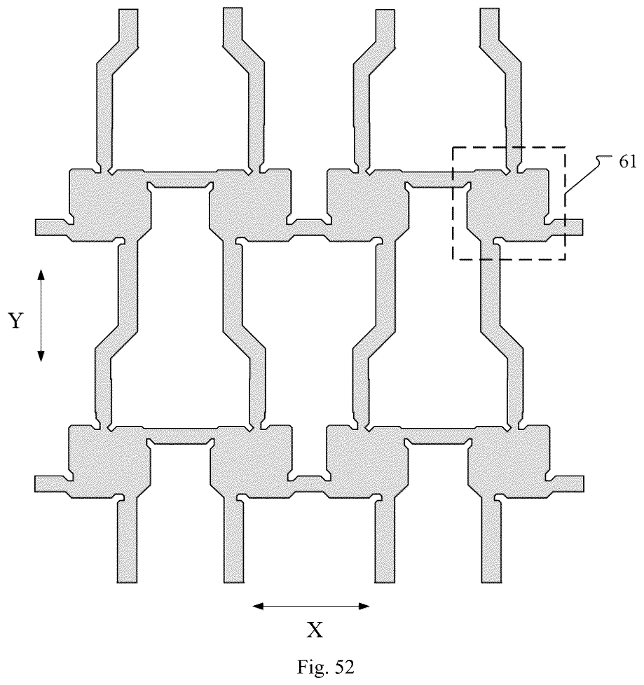

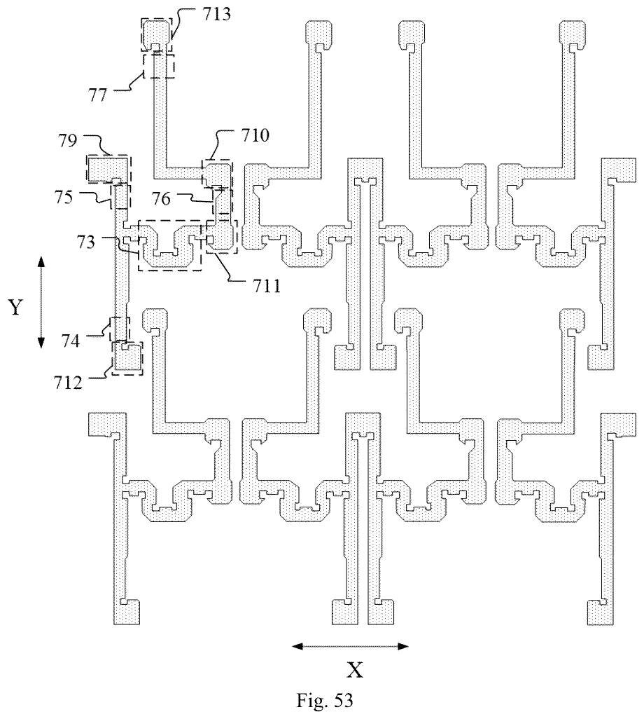

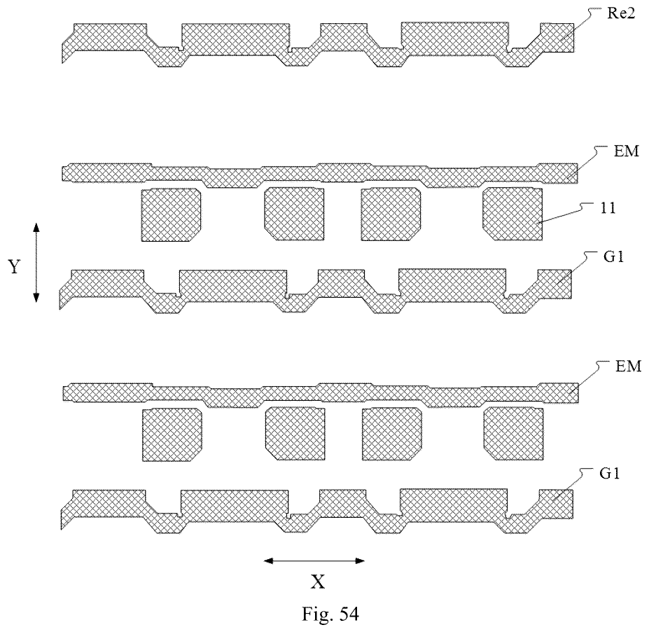

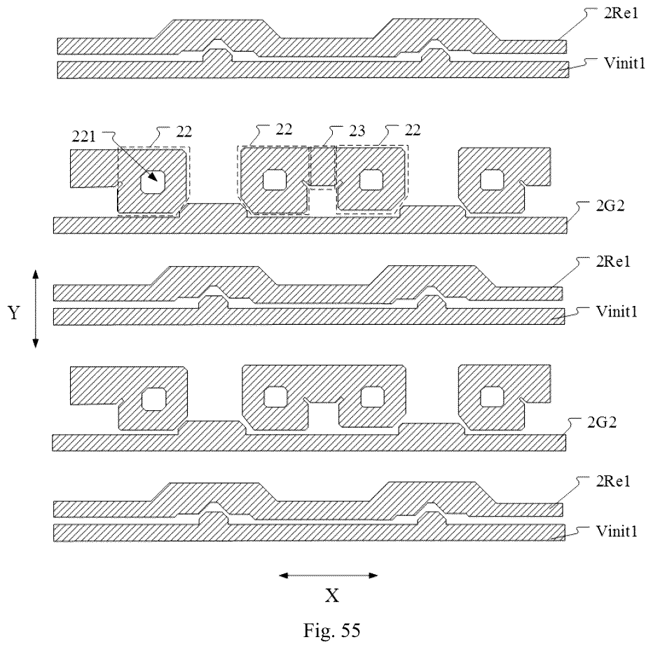

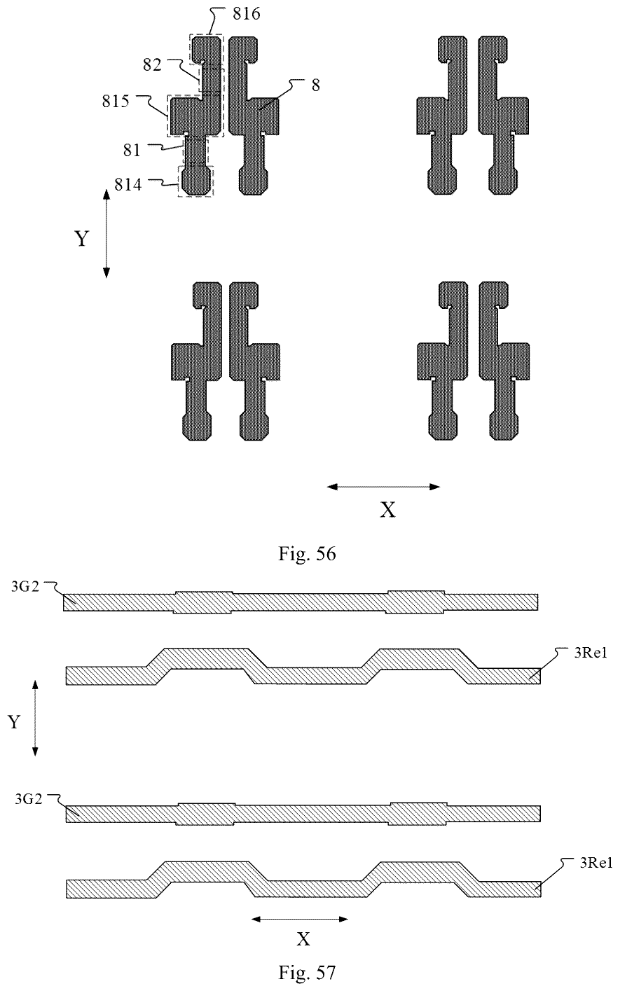

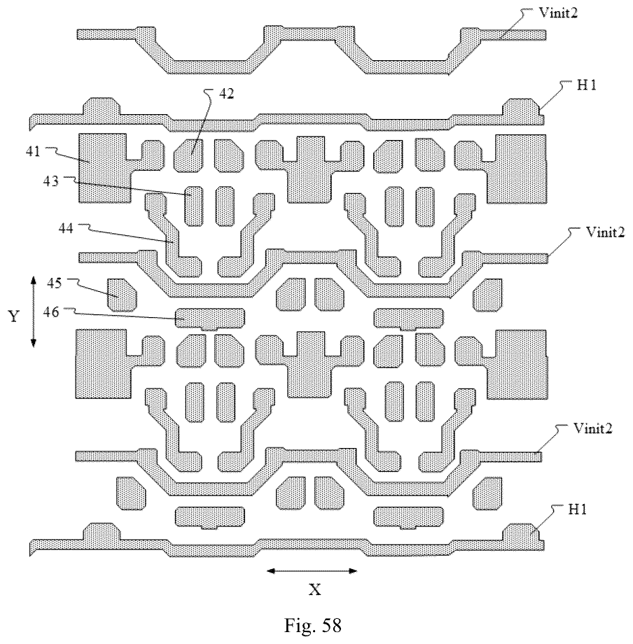

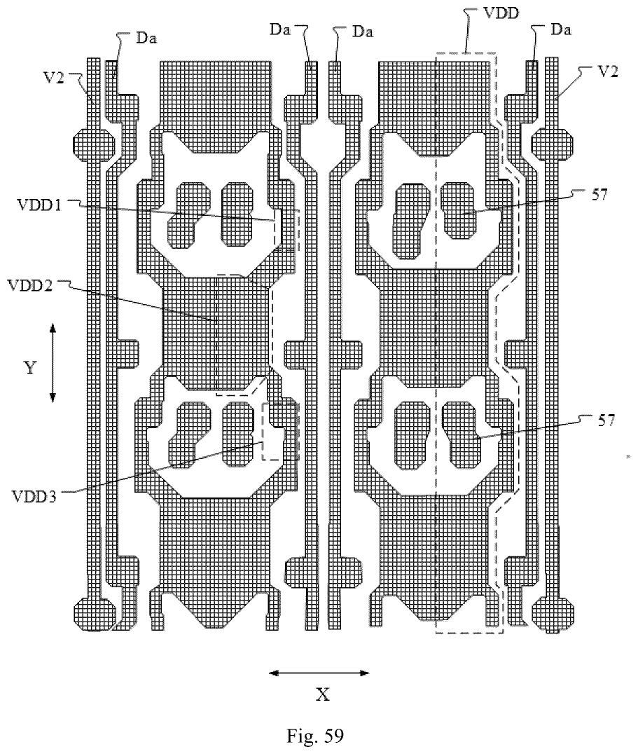

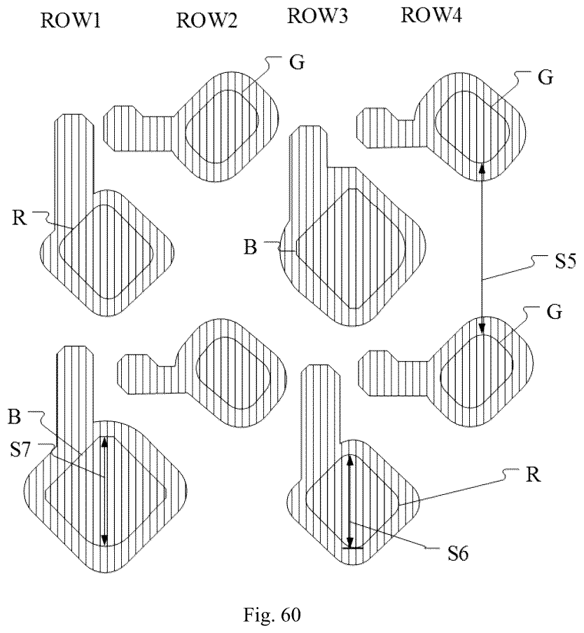

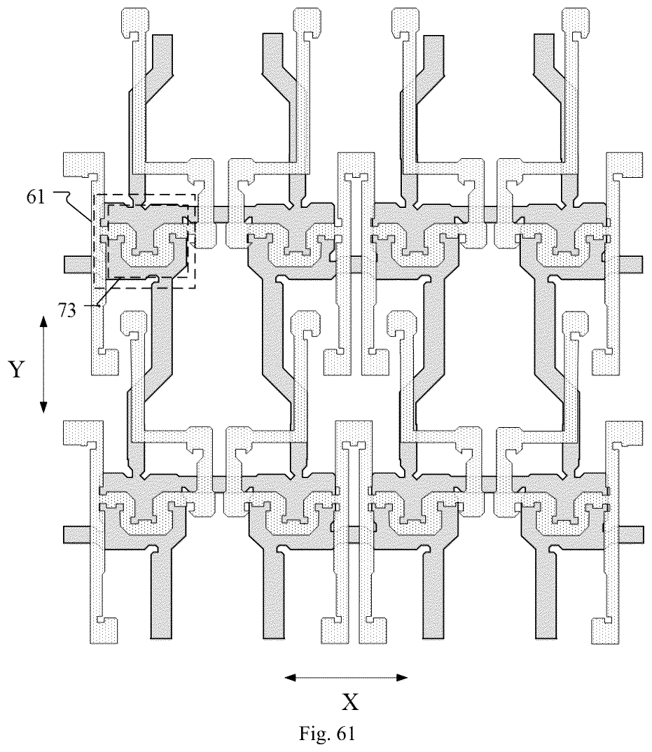

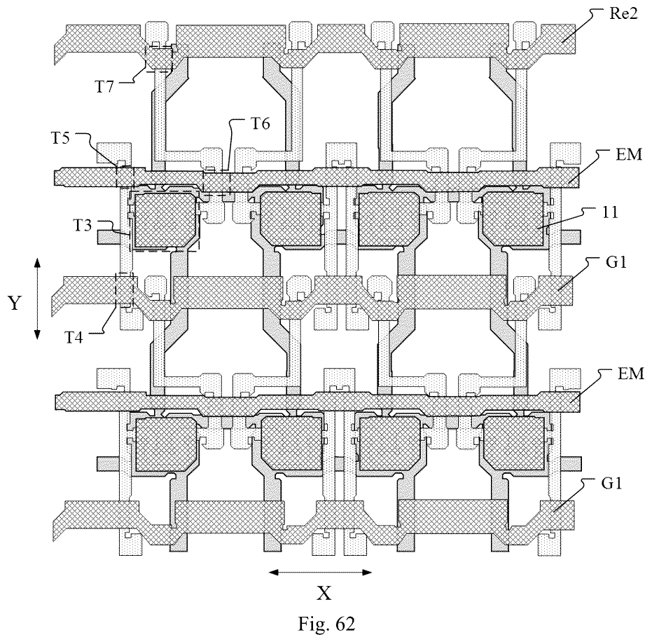

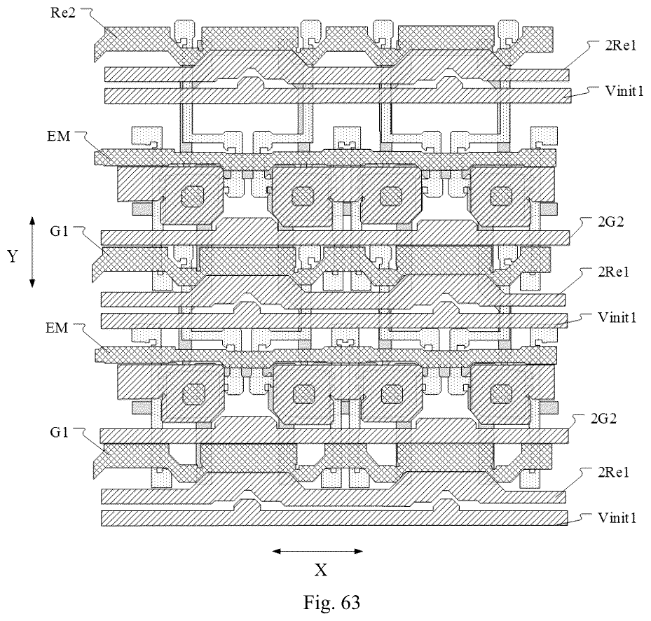

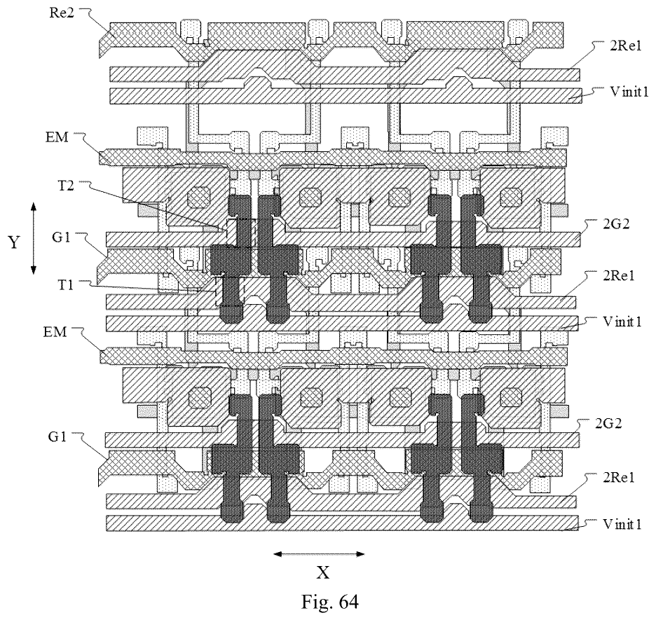

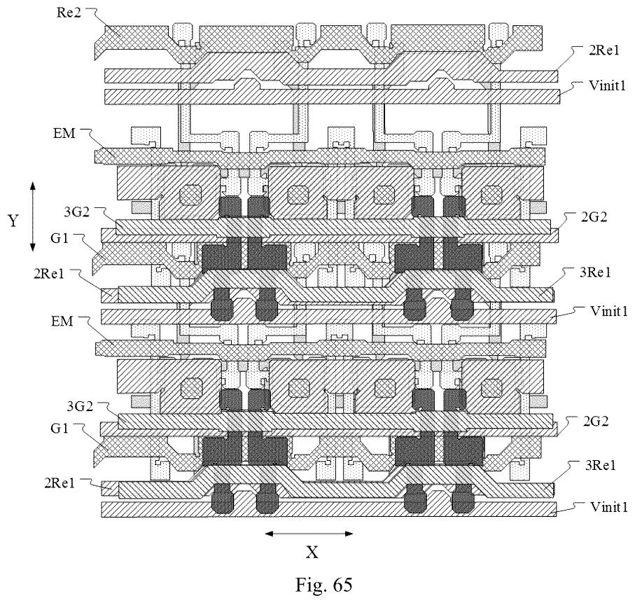

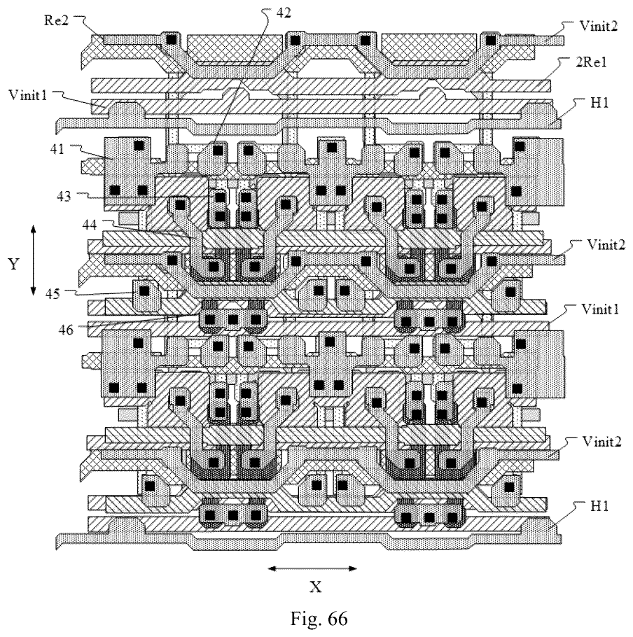

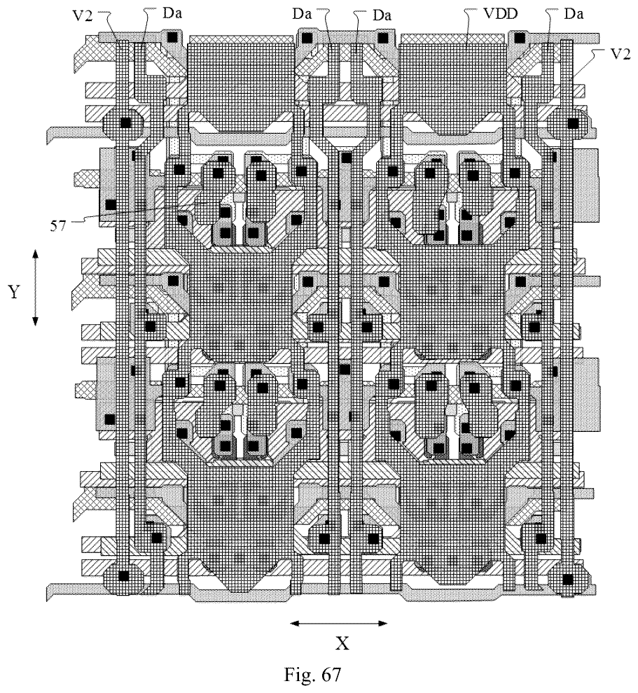

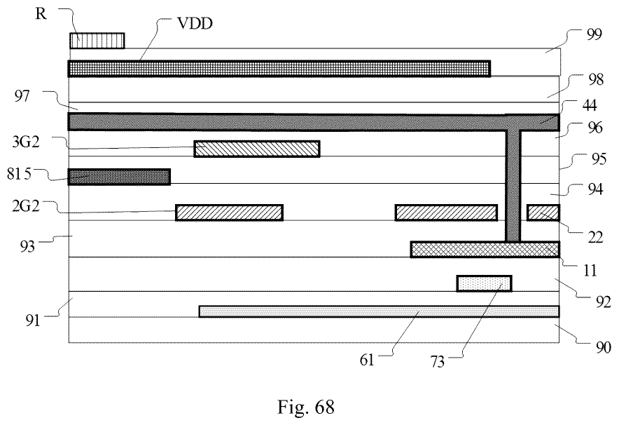

In an exemplary embodiment, the display panel may include a base substrate, a shielding layer, a first active layer, a first gate layer, a second gate layer, a second active layer, a third gate layer, a first source-drain layer, a second source-drain layer, and an electrode layer stacked in sequence. An insulation layer may be provided between adjacent layers. As shown in FIGS. 34-50, FIG. 34 is a partial layout of the sixth area K6 in FIG. 2, FIG. 35 is a structural layout of the shielding layer in FIG. 34, FIG. 36 is a structural layout of the first active layer in FIG. 34, FIG. 37 is a structural layout of the first gate layer in FIG. 34, FIG. 38 is a structural layout of the second gate layer in FIG. 34, FIG. 39 is a structural layout of the second active layer in FIG. 34, FIG. 40 is a structural layout of the third active layer in FIG. 34, FIG. 41 is a structural layout of the first source-drain layer in FIG. 34, FIG. 42 is a structural layout of the second source-drain layer in FIG. 34, FIG. 43 is a structural layout of the electrode layer in FIG. 34, FIG. 44 is a structural layout of the shielding layer and the first active layer in FIG. 34, FIG. 45 is a structural layout of the shielding layer, the first active layer and the first gate layer in FIG. 34, FIG. 46 is a structural layout of the shielding layer, the first active layer, the first gate layer, and the second gate layer in FIG. 34, FIG. 47 shows a structural layout of the shielding layer, the first active layer, the first gate layer, the second gate layer, and the second active layer in FIG. 34, FIG. 48 is a structural layout of the shielding layer, the first active layer, the first gate layer, the second gate layer, the second active layer, and the third gate layer in FIG. 34, FIG. 49 is a structural layout of the shielding layer, the first active layer, the first gate layer, the second gate layer, the second active layer, the third gate layer, and the first source-drain layer in FIG. 34, and FIG. 50 is a structural layout of the shielding layer, the first active layer, the first gate layer, the second gate layer, the second active layer, the third gate layer, the first source-drain layer, and the second source-drain layer in FIG. 34. The display panel may include a plurality of pixel driving circuits shown in FIG. 32. As shown in FIG. 50, the plurality of pixel driving circuits may include a first pixel driving circuit P1 and a second pixel driving circuit P2 adjacently arranged in the first direction X. The first pixel driving circuit P1 and the second pixel driving circuit P2 may be arranged in mirror symmetry with relative to the mirror symmetry plane DD. The mirror symmetry plane DD may be perpendicular to the base substrate. The orthographic projection of the first pixel driving circuit P1 on the base substrate and the orthographic projection of the second pixel driving circuit P2 on the base substrate may be arranged symmetrically with the intersection line between the mirror symmetry plane DD and the base substrate being the symmetry axis. The first pixel driving circuit P1 and the second pixel driving circuit P2 may form a repetition sub-unit. The display panel may include a plurality of repetition sub-units arranged in an array in the first direction X and the second direction Y. Four repetition sub-units arranged in a two-by-two array may form a repetition unit Pc. As shown in FIGS. 51-67, FIG. 51 is a structural layout of a single repetition unit in FIG. 34, FIG. 52 is a structural layout of the shielding layer in FIG. 51, FIG. 53 is a structural layout of the first active layer in FIG. 51, FIG. 54 is a structural layout of the first gate layer in FIG. 51, FIG. 55 is a structural layout of the second gate layer in FIG. 51, FIG. 56 is a structural layout of the second active layer in FIG. 51, FIG. 57 is a structural layout of the third gate layer in FIG. 51, FIG. 58 is a structural layout of the first source-drain layer in FIG. 51, FIG. 59 is a structural layout of the second source-drain layer in FIG. 51, FIG. 60 is a structural layout of the electrode layer in FIG. 51, FIG. 61 is a structural layout of the shielding layer and the first active layer in FIG. 51, FIG. 62 is a structural layout of the shielding layer, the first active layer and the first gate layer in FIG. 51, FIG. 63 is a structural layout of the shielding layer, the first active layer, the first gate layer, and the second gate layer in FIG. 51, FIG. 64 is a structural layout of the shielding layer, the first active layer, the first gate layer, the second gate layer, and the second active layer in FIG. 51, FIG. 65 is a structural layout of the shielding layer, the first active layer, the first gate layer, the second gate layer, the second active layer, and the third gate layer in FIG. 51, FIG. 66 is a structural layout of the shielding layer, the first active layer, the first gate layer, the second gate layer, the second active layer, the third gate layer and the first source-drain layer in FIG. 51, and FIG. 67 is a structural layout of the shielding layer, the first active layer, the first gate layer, the second gate layer, the second active layer, the third gate layer, the first source-drain layer, and the second source-drain layer in FIG. 51.

In an exemplary embodiment, the above-mentioned first signal line and second signal line may be added to the display panel by compressing repetition units. The plurality of repetition units arranged in the first direction X forms a row of repetition units. Each row of repetition units is correspondingly provided with a respective first signal line H1. A respective second signal line V2 is provided correspondingly between adjacent repetition units in the first direction X.

As shown in FIGS. 34, 35, 44, 51, 52, and 61, the shielding layer may include a plurality of shielding portions 61, and adjacent shielding portions 61 may be connected to each other. As shown in FIG. 35, among adjacent repetition units in the first direction X, the minimum distance in the first direction X between the orthographic projections of adjacent shielding portions 61 on the base substrate is L5; and among two repetition sub-units located in the same repetition unit and being adjacent in the first direction X, the minimum distance in the first direction X between the orthographic projections of adjacent shielding portions 61 on the base substrate is L6. L6 is smaller than L5. Among adjacent repetition units in the second direction Y, the minimum distance in the second direction Y between the orthographic projections of adjacent shielding portions 61 on the base substrate is L16; and among two repetition sub-units located in the same repetition unit and being adjacent in the second direction Y, the minimum distance in the second direction Y between the orthographic projections of adjacent shielding portions 61 on the base substrate is L15. L15 is smaller than L16. It should be understood that in other exemplary embodiments, the display panel may not include the shielding layer.

As shown in FIGS. 34, 36, 45, 51, 53, and 62, the first active layer may include a third active portion 73, a fourth active portion 74, a fifth active portion 75, a sixth active portion 76, and a seventh active portion 77. The third active portion 73 may be used to form a channel region of the driving transistor T3. The fourth active portion 74 may be used to form a channel region of the fourth transistor T4. The fifth active portion 75 may be used to form a channel region of the fifth transistor T5. The sixth active portion 76 may be used to form a channel region of the sixth transistor T6. The seventh active portion 77 may be used to form a channel region of the seventh transistor T7. The first active layer also includes a ninth active portion 79, a tenth active portion 710, an eleventh active portion 711, a twelfth active portion 712, and a thirteenth active portion 713. The ninth active portion 79 is connected to the side of the fifth active portion 75 away from the third active portion 73. The ninth active portion 79 is connected between two adjacent fifth active portions 75 in the repetition sub-units being adjacent in the first direction X. The tenth active portion 710 is connected between the sixth active portion 76 and the seventh active portion 77. The eleventh active portion 711 is connected between the sixth active portion 76 and the third active portion 73. The twelfth active portion 712 is connected to an end of the fourth active portion 74 away from the third active portion 73. The thirteenth active portion 713 is connected to an end of the seventh active portion 77 away from the sixth active portion 76. The orthographic projection of the shielding portion 61 on the base substrate may cover the orthographic projection of the third active portion 73 on the base substrate. The shielding portion 61 can reduce the impact of light on the driving characteristics of the driving transistor T3. As shown in FIG. 36, among adjacent repetition units in the first direction X, the dimension in the first direction X of the orthographic projection on the base substrate of the ninth active portion 79 connected between adjacent fifth active portions 75 is L7; and among two repetition sub-units located in the same repetition unit and being adjacent in the first direction X, the dimension in the first direction X of the orthographic projection on the base substrate of the ninth active portion 79 connected between adjacent fifth active portions 75 is L8, where L7 is larger than L8. Among adjacent repetition units in the second direction Y, the minimum distance in the second direction Y between the orthographic projections of adjacent twelfth active portion 712 and ninth active portion 79 on the base substrate is L18. Among two repetition sub-units located in the same repetition unit and being adjacent in the second direction Y, the minimum distance in the second direction Y between the orthographic projections of adjacent twelfth active portion 712 and ninth active portion 79 on the base substrate is L17. L18 is greater than L17. The first active layer may be formed of polysilicon material. Accordingly, the driving transistor T3, the fourth transistor T4, the fifth transistor T5, the sixth transistor T6, and the seventh transistor T7 may be P-type low-temperature polysilicon thin film transistors.

As shown in FIGS. 34, 37, 45, 51, 54, and 62, the first gate layer may include a first conductive portion 11, a first gate line G1, an enable signal line EM, and a second reset signal line Re2. The first gate line G1 may be used to provide the first gate drive signal terminal in FIG. 32. The enable signal line EM may be used to provide the enable signal terminal in FIG. 32. The second reset signal line Re2 may be used to provide the second reset signal terminal in FIG. 32. The orthographic projection of the first gate line G1 on the base substrate, the orthographic projection of the enable signal line EM on the base substrate, and the orthographic projection of the second reset signal line Re2 on the base substrate may all extend along the first direction X. The orthographic projection of the first gate line G1 on the base substrate covers the orthographic projection of the fourth active portion 74 on the base substrate. A partial structure of the first gate line G1 is used to form the gate of the fourth transistor. The orthographic projection of the enable signal line EM on the base substrate covers the orthographic projection of the fifth active portion 75 on the base substrate and the orthographic projection of the sixth active portion 76 on the base substrate. A partial structure of the enable signal line EM may be used to form gates of the fifth transistor T5 and the sixth transistor T6 respectively. The orthographic projection of the second reset signal line Re2 on the base substrate may cover the orthographic projection of the seventh active portion 77 on the base substrate. A partial structure of the second reset signal line Re2 may be used to form the gate of the seventh transistor T7. The orthographic projection of the first conductive portion 11 on the base substrate covers the orthographic projection of the third active portion 73 on the base substrate. The first conductive portion 11 may be used to form the gate of the driving transistor T3 and the first electrode of the capacitor C. As shown in FIGS. 45 and 62, the first gate line G1 in a row of pixel driving circuits may be multiplexed as the second reset signal line Re2 in the next row of pixel driving circuits. The display panel may be driven row by row from top to bottom or from bottom to top. This arrangement can improve the integration level of the pixel driving circuits and reduce the layout area of the pixel driving circuits. The shielding layer may also be connected to a stable power terminal. For example, the shielding layer may be connected to the first power terminal, the first initial signal terminal, the second initial signal terminal, etc. in FIG. 32. The shielding portion 61 may shield the noise impact of other signals on the driving transistor T3. As shown in FIG. 50, a plurality of repetition units arranged in the first direction X forms a row of repetition units. The same row of repetition units includes a first row of pixel driving circuits Ph1 and a second row of pixel driving circuits Ph2. The first row of pixel driving circuits Ph1 includes a plurality of pixel driving circuits arranged along the first direction X. The second row of pixel driving circuits Ph2 includes a plurality of pixel driving circuits arranged along the first direction. As shown in FIG. 37, in the first row of pixel driving circuits Ph1, the minimum distance in the second direction Y between the orthographic projection of the enable signal line EM on the base substrate and the orthographic projection of the second reset signal line Re2 on the base substrate is L3; and in the second row of pixel driving circuits Ph2, the distance in the second direction between the orthographic projection of the enable signal line EM on the base substrate and the orthographic projection of the second reset signal line Re2 on the base substrate is L4, where L3 is greater than L4. Among adjacent repetition units in the first direction X, the minimum distance in the first direction X between the orthographic projections of adjacent first conductive portions 11 on the base substrate is L19; and among two repetition sub-units located in the same repetition unit and being adjacent in the first direction X, the minimum distance in the first direction X between the orthographic projections of adjacent first conductive portions 11 on the base substrate is L20, where L20 is smaller than L19. In addition, the display panel may use the first gate layer as a mask to perform a conducting process on the first active layer. That is, the area of the first active layer covered by the first gate layer may form the channel region of the transistor, and the area of the first active layer not covered by the first gate layer forms a conductor structure.

As shown in FIGS. 34, 38, 46, 51, 55, and 63, the second gate layer may include a first initial signal line Vinit1, a third reset signal line 2Re1, a third gate line 2G2, and a plurality of second conductive portions 22. The first initial signal line Vinit1 is used to provide the first initial signal terminal in FIG. 32. The third reset signal line 2Re1 may be used to provide the first reset signal terminal in FIG. 32. The third gate line 2G2 may be used to provide the second gate drive signal terminal in FIG. 32. The orthographic projection of the first initial signal line Vinit1 on the base substrate, the orthographic projection of the third reset signal line 2Re1 on the base substrate, and the orthographic projection of the third gate line 2G2 on the base substrate may all extend along the first direction X. As shown in FIGS. 38 and 55, the second gate layer may also include a plurality of connecting portions 23. Among adjacent repetition sub-units in the first direction X, the connecting portion 23 is connected between two adjacent second conductive portions 22 in the first direction X. As shown in FIG. 38, among adjacent repetition units in the first direction X, the dimension in the first direction X of the orthographic projection on the base substrate of the connecting portion 23 connected between adjacent second conductive portions 22 is L10; and among two repetition sub-units located in the same repetition unit and being adjacent in the first direction X, the dimension in the first direction X of the orthographic projection on the base substrate of the connecting portion 23 connected between adjacent second conductive portions 22 is L9, where L10 is larger than L9. Among adjacent repetition units in the second direction Y, the dimension in the first direction X of the orthographic projection of adjacent second conductive portion and first initial signal line Vinit1 on the base substrate is L22; and among two repetition sub-units located in the same repetition unit and being adjacent in the second direction Y, the dimension in the first direction X of the orthographic projection of adjacent second conductive portion and first initial signal line Vinit1 on the base substrate is L21, where L22 is larger than L21. Furthermore, in other exemplary embodiments, adjacent second conductive portions 22 in the same repetition unit may also be connected.

As shown in FIGS. 34, 39, 47, 51, 56, and 64, the second active layer may include an active portion 8. The active portion 8 may include a first active portion 81, a second active portion 82, a fourteenth active portion 814, a fifteenth active portion 815, and a sixteenth active portion 816. The first active portion 81 is used to form a channel region of the first transistor T1. The second active portion 82 is used to form a channel region of the second transistor T2. The fifteenth active portion 815 is connected between the first active portion 81 and the second active portion 82. The fourteenth active portion 814 is connected to an end of the first active portion 81 away from the second active portion 82. The sixteenth active portion 816 is connected to an end of the second active portion 82 away from the first active portion 81. As shown in FIG. 39, among adjacent repetition units in the first direction X, the minimum distance in the first direction X between the orthographic projections on the base substrate of adjacent active portions 8 in the first direction X is L11; and among two repetition sub-units located in the same repetition unit and being adjacent in the first direction X, the minimum distance in the first direction X between the orthographic projections on the base substrate of adjacent active portions 8 in the first direction X is L12, where L11 is greater than L12. Among adjacent repetition units in the second direction Y, the minimum distance in the second direction Y between the orthographic projections on the base substrate of adjacent active portions 8 in the second direction Y is L24; and among two repetition sub-units located in the same repetition unit and being adjacent in the second direction Y, the minimum distance in the second direction Y between the orthographic projections on the base substrate of adjacent active portions 8 in the second direction Y is L23, where L24 is larger than L23. The second active layer may be formed of indium gallium zinc oxide. Accordingly, the first transistor T1 and the second transistor T2 may be N-type metal oxide thin film transistors. The orthographic projection of the third gate line 2G2 on the base substrate may cover the orthographic projection of the second active portion 82 on the base substrate. A partial structure of the third gate line 2G2 may be used to form the bottom gate of the second transistor T2. The orthographic projection of the third reset signal line 2Re1 on the base substrate may cover the orthographic projection of the first active portion 81 on the base substrate. A partial structure of the third reset signal line 2Re1 may be used to form the bottom gate of the first transistor T1.

As shown in FIGS. 34, 40, 48, 51, 57, and 65, the third gate layer may include a first reset signal line 3Re1 and a second gate line 3G2. Both the orthographic projection of the first reset signal line 3Re1 on the base substrate and the orthographic projection of the second gate line 3G2 on the base substrate may extend along the first direction X. The first reset signal line 3Re1 may be used to provide the first reset signal terminal in FIG. 32. The orthographic projection of the first reset signal line 3Re1 on the base substrate may cover the orthographic projection of the first active portion 81 on the base substrate. A partial structure of the first reset signal line 3Re1 may be used to form the top gate of the first transistor T1. At the same time, the first reset signal line 3Re1 may be connected to the third reset signal line 2Re1 through a via hole located in the frame area of the display panel. The second gate line 3G2 may be used to provide the second gate drive signal terminal in FIG. 32. The orthographic projection of the second gate line 3G2 on the base substrate may cover the orthographic projection of the second active portion 82 on the base substrate. A partial structure of the second gate line 3G2 may be used to form the top gate of the second transistor T2. At the same time, the second gate line 3G2 may be connected to the third gate line 2G2 through a via hole located in the frame area of the display panel. As shown in FIG. 40, among adjacent repetition units in the second direction Y, the minimum distance in the second direction Y between the orthographic projections of adjacent second gate line 3G2 and first reset signal line 3Re1 on the base substrate is L14; and among repetition sub-units located in the same repetition unit and being adjacent in the second direction Y, the minimum distance in the second direction Y between the orthographic projections of adjacent second gate line 3G2 and first reset signal line 3Re1 on the base substrate is L13, where L14 is greater than L13. In addition, the display panel may use the third gate layer as a mask to perform a conducting process on the second active layer. That is, the area of the second active layer covered by the third gate layer may form the channel region of the transistor, and the area of the second active layer not covered by the third gate layer forms a conductor structure.

As shown in FIGS. 34, 41, 49, 51, 58, and 66, the first source-drain layer may include the above-mentioned first signal line H1, second initial signal line Vinit2, first bridge portion 41, second bridge portion 42, third bridge portion 43, fourth bridge portion 44, fifth bridge portion 45, and sixth bridge portion 46. The first bridge portion 41 is connected to the connecting portion 23 and the ninth active portion 79 through via holes respectively, so as to connect the first terminal of the fifth transistor and the second electrode of the capacitor C. Adjacent repetition sub-units in the first direction X share the same first bridge portion 41. The second bridge portion 42 may be connected to the tenth active portion 710 through a via hole, so as to connect the second terminal of the sixth transistor T6 and the second terminal of the seventh transistor T7. The third bridge portion 43 may be connected to the eleventh active portion 711 and the sixteenth active portion 816 respectively through via holes, so as to connect the second terminal of the second transistor T2, the first terminal of the sixth transistor T6, and the second terminal of the driving transistor T3. The fourth bridge portion 44 may be connected to the fifteenth active portion 815 and the first conductive portion 11 through via holes respectively, so as to connect the first terminal of the second transistor T2 and the gate of the driving transistor. An opening 221 is formed on the second conductive portion 22. The orthographic projection of the via hole connected between the first conductive portion 11 and the fourth bridge portion 44 on the base substrate is located within the orthographic projection of the opening 221 on the base substrate. Thus, the via hole and the second conductive portion 22 are insulated from each other. The fifth bridge portion 45 may be connected to the twelfth active portion 712 through a via hole so as to connect the first terminal of the fourth transistor. The sixth bridge portion 46 may be connected to the fourteenth active portion 814 and the first initial signal line Vinit1 through via holes respectively, so as to connect the first terminal of the first transistor and the first initial signal terminal. In the same repetition unit, two adjacent pixel driving circuits may share the same sixth bridge portion 46. The second initial signal line Vinit2 may be used to provide the second initial signal terminal in FIG. 32. The orthographic projection of the second initial signal line Vinit2 on the base substrate may extend along the first direction X, and the second initial signal line Vinit2 may be connected to the thirteenth active portion 713 through a via hole, so as to connect the first terminal of the seventh transistor and the second initial signal terminal. The plurality of repetition units arranged in the first direction X forms a row of repetition units. Each row of repetition units is correspondingly provided with a respective first signal line H1. The orthographic projection of the first signal line H1 on the base substrate is located between the orthographic projection on the base substrate of the enable signal line EM in the first row of pixel driving circuits Ph1 and the orthographic projection on the base substrate of the second reset signal line Re2 in the first row of pixel driving circuits Ph1. The orthographic projection of the first signal line H1 on the base substrate does not overlap with the orthographic projections of the first gate layer and the third gate layer on the base substrate. The orthographic projection of the first signal line H1 on the base substrate only overlaps with the orthographic projection on the base substrate of the first initial signal line located on the second gate layer and part of the first active layer. This arrangement can reduce the parasitic capacitance of the first signal line and reduce the coupling effect between the first signal line and other signal lines. Among adjacent columns of repetition units in the first direction X, the maximum dimension in the first direction X of the orthographic projection on the base substrate of the first bridge portion 41 shared by adjacent repetition sub-units is L15; and in the same repetition unit, the maximum dimension in the first direction X of the orthographic projection on the base substrate of the first bridge portion 41 shared by adjacent repetition sub-units in the first direction X is L16, where L15 is larger than L16. The maximum distance in the second direction Y between the orthographic projection of the first bridge portion 41 on the base substrate and the orthographic projection of the second initial signal line Vinit2 on the base substrate in the first row of pixel driving circuits Ph1 is L26, and the maximum distance in the second direction Y between the orthographic projection of the first bridge portion 41 on the base substrate and the orthographic projection of the second initial signal line Vinit2 on the base substrate in the second row of pixel driving circuits Ph2 is L25, where L26 is greater than L25.

As shown in FIGS. 34, 42, 50, 51, 59, and 67, the second source-drain layer may include the above-mentioned second signal line V2, a plurality of power lines VDD, a plurality of data lines Da, and the seventh bridge portion 57. A respective second signal line V2 is provided correspondingly between adjacent repetition units in the first direction X. The orthographic projection of the power line VDD on the base substrate and the orthographic projection of the data line Da on the base substrate may both extend along the second direction Y. The power line VDD may be used to provide the first power terminal in FIG. 32. The data line Da may be used to provide the data signal terminal in FIG. 32. Each column of pixel driving circuits may be provided with a respective power line VDD. The power line VDD may be connected to the first bridge portion 41 through a via hole, so as to connect the first terminal of the fifth transistor and the first power terminal. The data line Da may be connected to the fifth bridge portion 45 through a via hole, so as to connect the first terminal of the fourth transistor and the data signal terminal. The seventh bridge portion 57 may be connected to the second bridge portion 42 through a via hole, so as to connect the second terminal of the seventh transistor. In the same repetition sub-unit, adjacent power lines VDD are connected to each other, so that the power line VDD and the second conductive portion 22 can form a grid structure. The power line of the grid structure can reduce the voltage drop of the power signal thereon.

As shown in FIGS. 34, 42, 50, 51, 59, and 67, the power line VDD may include a first power line segment VDD1, a second power line segment VDD2, and a third power line segment VDD3. The second power line segment VDD2 is connected between the first power line segment VDD1 and the third power line segment VDD3. The dimension in the first direction X of the orthographic projection of the second power line segment VDD2 on the base substrate may be larger than the dimension in the first direction X of the orthographic projection of the first power line segment VDD1 on the base substrate. The dimension in the first direction X of the orthographic projection of the second power line segment VDD2 on the base substrate may be larger the dimension in the first direction X of the orthographic projection of the third power line segment VDD3 on the base substrate. In addition, the orthographic projection of the second power line segment VDD2 on the base substrate may also cover the orthographic projection of the first active portion 81 on the base substrate and the orthographic projection of the second active portion 82 on the base substrate. The second power line segment VDD2 can reduce the impact of light on the characteristics of the first transistor T1 and the second transistor T2. In addition, the orthographic projection of the power line VDD on the base substrate may also at least partially overlap with the orthographic projection of the fourth bridge portion 44 on the base substrate. The power line VDD may be used to shield the noise interference on the fourth bridge portion 44 by other signals, thereby improving the stability of the gate voltage of the driving transistor T3. As shown in FIG. 42, among adjacent columns of repetition units in the first direction X, the minimum distance in the first direction X between the orthographic projections of two adjacent data lines Da on the base substrate is L1; and among two repetition sub-units located in the same repetition unit and adjacent in the first direction X, the distance in the first direction X between the orthographic projections of two adjacent data lines Da on the base substrate is L2, where L1 is greater than L2.

As shown in FIGS. 34, 43, 51, and 60, the pixel electrode layer may include a plurality of electrode portions: a first electrode portion R, a second electrode portion B, and a third electrode portion G. In the same electrode row, the first electrode portion R, the third electrode portion G, the second electrode portion B, and the third electrode portion G are sequentially arranged alternately in the first direction X. The plurality of electrode portions forms a plurality of electrode rows. The plurality of electrode rows includes sequentially adjacent first electrode row ROW1, second electrode row ROW2, third electrode row ROW3, and fourth electrode row ROW4. The first electrode row ROW1 includes the first electrode portion R and the second electrode portion B that are arranged alternately in the second direction Y. The second electrode row ROW2 includes a plurality of third electrode portions G arranged in the second direction Y. The third electrode row ROW3 includes the second electrode portions B and the first electrode portions R that are arranged alternately in sequence in the second direction Y. The fourth electrode row ROW4 includes a plurality of third electrode portions G arranged in the second direction Y. The minimum distance S5 in the second direction Y between the orthographic projections on the base substrate of two third electrode portions G located in adjacent electrode rows of the same electrode column is greater than the dimension S6 in the second direction of the orthographic projection on the base substrate of the first electrode portion R, or larger than the dimension S7 in the second direction Y of the orthographic projection on the base substrate of the second electrode portion B. The orthographic projection of the first electrode portion R on the base substrate coincides with the orthographic projection on the base substrate of the respective pixel opening on the pixel definition layer. The orthographic projection of the third electrode portion G on the base substrate coincides with the orthographic projection on the base substrate of the respective pixel opening on the pixel definition layer. The orthographic projection of the second electrode portion B on the base substrate coincides with the orthographic projection on the base substrate of the respective opening on the pixel definition layer. In the same repetition unit, two second power line segments VDD2 in adjacent power lines VDD are connected.

As shown in FIG. 34, among two adjacent repetition sub-units in the first direction, the orthographic projections of two adjacent data lines Da on the base substrate intersect the orthographic projection of the same third electrode portion G on the base substrate, and are located on both sides of the orthographic projection of the second signal line V2 on the base substrate. The orthographic projection of the second signal line V2 on the base substrate intersects the third electrode portion. This arrangement can improve the flatness of the electrode portion, thereby improving the display uniformity of the display panel.

It should be noted that, as shown in FIGS. 34, 49, 50, 51, 66, and 67, the black square shown on the side of the first source-drain layer away from the base substrate indicates the via hole of the first source-drain layer connected to other layers on the side facing the base substrate. The black square shown on the side of the second source-drain layer away from the base substrate indicates the via hole of the second source-drain layer connected to other layers on the side facing the base substrate. The black square shown on the side of the electrode layer away from the base substrate represent the via hole of the electrode layer connected to other layers on the side facing the base substrate. The black square only represents the location of the via hole. Different via holes represented by black squares at different positions may penetrate different insulation layers.

In an exemplary embodiment, a respective second signal line V2 is provided correspondingly between two adjacent columns of repetition units in the first direction, and a respective first signal line H1 is provided correspondingly in the same row of repetition units. In an exemplary embodiment, the repetition unit includes two rows and two columns of repetition sub-units. It should be understood that in other exemplary embodiments, the repetition unit may also include repetition sub-units with other numbers of rows and columns.

As shown in FIG. 68, it is a partial cross-sectional view of the display panel in FIG. 51 taken along the dotted line EE. The display panel may further include a first insulation layer 91, a second insulation layer 92, a third insulation layer 93, a fourth insulation layer 94, a fifth insulation layer 95, a first dielectric layer 96, a passivation layer 97, a first planarization layer 98, and a second planarization layer 99. The base substrate 90, the shielding layer, the first insulation layer 91, the first active layer, the second insulation layer 92, the first gate layer, the third insulation layer 93, the second gate layer, the fourth insulation layer 94, the second active layer, the fifth insulation layer 95, the third gate layer, the first dielectric layer 96, the first source-drain layer, the passivation layer 97, the first planarization layer 98, the second source-drain layer, and the second planarization layer 99 are stacked in sequence. The first insulation layer 91, the second insulation layer 92, the third insulation layer 93, the fourth insulation layer 94 and the fifth insulation layer 95 may be a single-layer structure or a multi-layer structure. The materials of the first insulation layer 91, the second insulation layer 92, the third insulation layer 93, the fourth insulation layer 94, and the fifth insulation layer 95 may be at least one of silicon nitride, silicon oxide, and silicon oxynitride. The first dielectric layer 96 may be silicon nitride layer. The materials of the first planarization layer 98 and the second planarization layer 99 may be organic materials, such as polyimide (PI), polyethylene terephthalate (PET), polyethylene naphthalate (PEN), silicon-glass bonding structure (SOG), and other materials. The passivation layer 97 may be a silicon oxide layer. The base substrate 90 may include a glass substrate, a barrier layer, and a polyimide layer that are stacked in sequence. The barrier layer may be an inorganic material. The materials of the first gate layer, the second gate layer, and the third gate layer may be one of molybdenum, aluminum, copper, titanium, niobium, or an alloy, or a molybdenum/titanium alloy or a laminate or other conductive layer. The materials of the first source-drain layer and the second source-drain layer may include a metal material, for example, one of molybdenum, aluminum, copper, titanium, niobium, or an alloy, or a molybdenum/titanium alloy or laminate, etc., or titanium/aluminum/titanium laminate, or other conductive layers. The sheet resistance of any one of the first source-drain layer and the second source-drain layer may be smaller than the sheet resistance of any one of the first gate layer, the second gate layer, and the third gate layer. Therefore, in an exemplary embodiment, the first data fan-out line and the second data fan-out line have smaller resistance.

It should be noted that the scale of the drawings in the present disclosure may be used as a reference in the actual process, but is not limited thereto. For example, the width-to-length ratio of the channel, the thickness and spacing of each film layer, the width and spacing of each signal line may be adjusted according to actual needs. The number of pixels in the display substrate and the number of sub-pixels in each pixel are not limited to the numbers shown in the drawings. The drawings described in the present disclosure are only structural schematic diagrams. In addition, the qualifiers such as first and second are only used to define different structure names and have no specific order meaning. The same structural layer may be formed through the same patterning process. In an exemplary embodiment, the orthographic projection of a certain structure on the base substrate extends along a certain direction. It can be understood that the orthographic projection of the structure on the base substrate extends straightly or in a bend way along the direction.

In an exemplary embodiment, the display panel may be a flexible display panel or a non-flexible display panel.

An exemplary embodiment also provides a display apparatus, which includes the above-mentioned display panel. The display apparatus may be a display device such as a mobile phone, a tablet computer, or a television.

Other embodiments of the present disclosure will be readily apparent to those skilled in the art from consideration of the specification and practice of the contents disclosed herein. The present application is intended to cover any variations, uses, or adaptations of the present disclosure that follow the general principles of the present disclosure and include common knowledge or customary technical means in the technical field that are not disclosed in the present disclosure. It is intended that the specification and examples be considered as exemplary only, with the true scope and spirit of the present disclosure being indicated by the following claims.

It is to be understood that the present disclosure is not limited to the precise structures described above and illustrated in the accompanying drawings, and various modifications and changes may be made without departing from the scope thereof. The scope of the present disclosure is limited only by the appended claims.

1. A display panel, comprising a display area and a fan-out area located in the display area, wherein the display panel further comprises:
a base substrate;
a plurality of data lines located in the display area, wherein orthographic projections of the data lines on the base substrate are arranged at intervals along a first direction and extend along a second direction, the first direction intersecting the second direction;
a plurality of first data fan-out lines located in the fan-out area, wherein orthographic projections of the first data fan-out lines on the base substrate are arranged at intervals along the second direction and extend along the first direction, and the first data fan-out line is arranged corresponding to and connected with a respective data line;
a plurality of second data fan-out lines located in the fan-out area, wherein orthographic projections of the second data fan-out lines on the base substrate are arranged at intervals along the first direction and extend along the second direction, and the second data fan-out line is arranged corresponding to and connected with a respective first data fan-out line.

2. The display panel according to claim 1, wherein the display panel further comprises:
a plurality of first signal lines located in the display area, wherein orthographic projections of the first signal lines on the base substrate extend along the first direction and are arranged at intervals along the second direction, the plurality of first signal lines comprises a first signal sub-line, and at least a partial structure of the first signal sub-line is used to form the first data fan-out line;
a plurality of second signal lines located in the display area and arranged on a different conductive layer than the first signal lines, wherein orthographic projections of the second signal lines on the base substrate extend along the second direction and are arranged at intervals along the first direction, the plurality of second signal lines comprises a second signal sub-line, and at least a partial structure of the second signal sub-line is used to form the second data fan-out line.

3. The display panel according to claim 2, wherein
the minimum distance in the second direction between orthographic projections of two adjacent first signal lines on the base substrate is S1, and the maximum distance in the second direction between orthographic projections of two adjacent first signal lines on the base substrate is S2, where (S2-S1)/S1 is greater than or equal to 0 and less than or equal to 0.2; and/or
the minimum distance in the first direction between orthographic projections of two adjacent second signal lines on the base substrate is S3, and the maximum distance in the first direction between orthographic projections of two adjacent second signal lines on the base substrate is S4, where (S4-S3)/S3 is greater than or equal to 0 and less than or equal to 0.2.

4. The display panel according to claim 2, wherein
the first signal sub-line further comprises a first simulation line spaced apart from the first data fan-out line, and the second signal sub-line further comprises a second simulation line spaced apart from the second data fan-out line;
the fan-out area comprises a first fan-out area and a second fan-out area, the first data fan-out line is located in the first fan-out area, and the second data fan-out line is located in the second fan-out area;
the plurality of first signal lines further comprises a third simulation line, and the third simulation line is located in the display area outside the first fan-out area;
the plurality of second signal lines further comprises a fourth simulation line, and the fourth simulation line is located in the display area outside the second fan-out area.

5. The display panel according to claim 4, wherein
the display panel further comprises a pixel driving circuit and a light-emitting unit, the pixel driving circuit being connected to a first electrode of the light-emitting unit;
the display panel further comprises a common electrode layer used to form a second electrode of the light-emitting unit; and
the first simulation line, the second simulation line, the third simulation line, and the fourth simulation line are connected to the common electrode layer.

6. The display panel according to claim 4, wherein
the first simulation line is connected through a via hole to the fourth simulation line that intersects an orthographic projection of the first simulation line on the base substrate; and
the third simulation line is connected through via holes to the second simulation line and the fourth simulation line that intersect an orthographic projection of the third simulation line on the base substrate.

7. (canceled)

8. The display panel according to claim 4, wherein
the first fan-out area comprises a first fan-out sub-area and a second fan-out sub-area, the first fan-out sub-area and the second fan-out sub-area being located on both sides in the first direction of the second fan-out area;
the plurality of second signal lines further comprises at least one fifth simulation line, wherein a partial structure of the fifth simulation line is located in the second fan-out area, and the fifth simulation line is connected through via holes respectively to the first simulation line and the third simulation line that intersect an orthographic projection of the fifth simulation line on the base substrate.

9. The display panel according to claim 2, wherein
the plurality of first signal lines is located on the same conductive layer, and the plurality of second signal lines is located on the same conductive layer; and
the conductive layer where the second signal line is located is arranged on a side away from the base substrate of the conductive layer where the first signal line is located.

10. (canceled)

11. The display panel according to claim 2, wherein
the first signal line comprises a plurality of first via contact portions and a first extension portion, wherein orthographic projections of the plurality of first via contact portions on the base substrate are arranged at intervals along the first direction, the first extension portion is connected to the first via contact portion, and an orthographic projection of the first via contact portion on the base substrate has a dimension in the second direction being greater than a dimension in the second direction of an orthographic projection of the first extension portion on the base substrate;
the second signal line comprises a plurality of second via contact portions and a second extension portion, wherein orthographic projections of the plurality of second via contact portions on the base substrate are arranged at intervals along the second direction, the second extension portion is connected to the second via contact portion, and an orthographic projection of the second via contact portion on the base substrate has a dimension in the first direction being larger than a dimension in the first direction of an orthographic projection of the second extension portion on the base substrate; and
the first via contact portion is arranged corresponding to a respective second via contact portion, the orthographic projection of the first via contact portion on the base substrate at least partially overlaps with the orthographic projection on the base substrate of the respective second via contact portion, and at least some of the first via contact portions are connected to the respective second via contact portions through via holes.

12-18. (canceled)

19. The display panel according to claim 11, wherein
the data line, the orthographic projection of which on the base substrate is located on adjacent sides of the second signal line, comprises a third extension portion, a fourth extension portion, and a fifth extension portion, the fourth extension portion being connected between the third extension portion and the fifth extension portion; and
at least partial structures of the second via contact portion and the fourth extension portion are oppositely disposed in the first direction, dimensions in the first direction of an orthographic projection of the fourth extension portion on the base substrate and an orthographic projection of the second extension portion on the base substrate are larger than dimensions in the first direction of an orthographic projection of the third extension portion on the base substrate and an orthographic projection of the second extension portion on the base substrate, dimensions in the first direction of an orthographic projection of the fourth extension portion on the base substrate and an orthographic projection of the second extension portion on the base substrate are larger than dimensions in the first direction of an orthographic projection of the fifth extension portion on the base substrate and an orthographic projection of the second extension portion on the base substrate.

20. The display panel according to claim 4, wherein
the display panel further comprises a pixel driving circuit and a light-emitting unit, the pixel driving circuit being connected to a first electrode of the light-emitting unit; and
the display panel further comprises an electrode layer located on a side of the base substrate, wherein the electrode layer comprises a plurality of electrode portions, and the electrode portion is used to form the first electrode of the light-emitting unit, wherein
an orthographic projection of a notch between the first data fan-out line and the first simulation line on the base substrate does not overlap with an orthographic projection of the electrode portion on the base substrate; and/or
an orthographic projection of a notch between the second data fan-out line and the second simulation line on the base substrate does not overlap with an orthographic projection of the electrode portion on the base substrate.

21. The display panel according to claim 11, wherein
the display panel further comprises a pixel driving circuit and a light-emitting unit, the pixel driving circuit being connected to a first electrode of the light-emitting unit;
the display panel further comprises an electrode layer located on a side of the base substrate, wherein the electrode layer comprises a plurality of electrode portions, and the electrode portion is used to form the first electrode of the light-emitting unit;
an orthographic projection of the first via contact portion on the base substrate does not overlap with an orthographic projection of the electrode portion on the base substrate; and
an orthographic projection of the second via contact portion on the base substrate does not overlap with an orthographic projection of the electrode portion on the base substrate.

22. The display panel according to claim 2, wherein
the display panel further comprises a plurality of pixel driving circuits and a plurality of light-emitting units, the plurality of pixel driving circuits being arranged in an array along the first direction and the second direction, and the pixel driving circuit being connected to a first electrode of the light-emitting unit;
the pixel driving circuit comprises a driving transistor, a sixth transistor, and a seventh transistor, wherein a first terminal of the sixth transistor is connected to a second terminal of the driving transistor, a second terminal of the sixth transistor is connected to the first electrode of the light-emitting unit, a first terminal of the seventh transistor is connected to a second initial signal line, and a second terminal of the seventh transistor is connected to the first electrode of the light-emitting unit; and
the display panel further comprises:
a first active layer located on a side of the base substrate, wherein the first active layer comprises a sixth active portion and a seventh active portion, the sixth active portion is used to form a channel region of the sixth transistor, and the seventh active portion is used to form a channel region of the seventh transistor; and
a first gate layer located on a side of the first active layer away from the base substrate, wherein the first gate layer comprises an enable signal line and a second reset signal line, an orthographic projection of the enable signal line on the base substrate extends along the first direction and covers an orthographic projection of the sixth active portion on the base substrate, and an orthographic projection of the second reset signal line on the base substrate extends along the first direction and covers an orthographic projection of the seventh active portion on the base substrate,
wherein the first direction is a row direction, and an orthographic projection of the first signal line on the base substrate is located between orthographic projections on the base substrate of the enable signal line and the second reset signal line in the same row of pixel driving circuits.

23. The display panel according to claim 11, wherein
the display panel further comprises a plurality of pixel driving circuits and a plurality of light-emitting units, the plurality of pixel driving circuits being arranged in an array along the first direction and the second direction, and the pixel driving circuit being connected to a first electrode of the light-emitting unit;
the pixel driving circuit comprises a driving transistor, a sixth transistor, and a first transistor, wherein a first terminal of the sixth transistor is connected to a second terminal of the driving transistor, a second terminal of the sixth transistor is connected to the first electrode of the light-emitting unit, a first terminal of the first transistor is connected to a first initial signal line, and a second terminal of the first transistor is connected to a gate of the driving transistor; and
the display panel further comprises:
a first gate layer located on a side of the base substrate, wherein the first gate layer comprises an enable signal line, and a partial structure of the enable signal line is used to form a gate of the sixth transistor, and
a second gate layer located on a side of the first gate layer away from the base substrate, the second gate layer comprising the first initial signal line,
wherein an orthographic projection on the base substrate of a first extension portion in the first signal line is located between an orthographic projection on the base substrate of the first initial signal line in the same row of pixel driving circuits and an orthographic projection on the base substrate of the enable signal line in an adjacent next row of pixel driving circuits.

24. The display panel according to claim 2, wherein
the display panel comprises a plurality of repetition units arranged in an array along the first direction and the second direction, wherein the repetition unit comprises n rows and m columns of repetition sub-units, n and m being positive integers greater than or equal to 1;
the repetition sub-unit comprises two pixel driving circuits arranged adjacently in the first direction, the two pixel driving circuits in the same repetition sub-unit being arranged in mirror symmetry;
a plurality of the repetition units arranged along the second direction form a column of repetition units, and one of the second signal lines is provided correspondingly between two adjacent columns of repetition units in the first direction; and
a plurality of the repetition units arranged along the first direction form a row of repetition units, and each row of repetition units is provided with a respective first signal line.

25. The display panel according to claim 24, wherein
the display panel further comprises a light-emitting unit, the pixel driving circuit being connected to a first electrode of the light-emitting unit;
the display panel further comprises an electrode layer, the electrode layer comprising a plurality of electrode portions, and the electrode portion being used to form the first electrode of the light-emitting unit; and
among two adjacent repetition sub-units in the first direction, orthographic projections of two adjacent data lines on the base substrate intersect an orthographic projection of the same electrode portion on the base substrate, and are located on both sides of an orthographic projection of the second signal line on the base substrate.

26. (canceled)

27. The display panel according to claim 24, wherein
n is a positive integer greater than or equal to 2;
the display panel further comprises a light-emitting unit, and the pixel driving circuit comprises a driving transistor, a sixth transistor, and a seventh transistor, wherein a first terminal of the sixth transistor is connected to a second terminal of the driving transistor, a second terminal of the sixth transistor is connected to a first electrode of the light-emitting unit, a gate of the sixth transistor is connected to an enable signal line, a first terminal of the seventh transistor is connected to a second initial signal line, a second terminal of the seventh transistor is connected to the first electrode of the light-emitting unit, and a gate of the seventh transistor is connected to a second reset signal line;
the same row of repetition units comprises a first row of pixel driving circuits and a second row of pixel driving circuits, wherein the first row of pixel driving circuits comprises a plurality of pixel driving circuits arranged along the first direction, and the second row of pixel driving circuit comprises a plurality of pixel driving circuits arranged along the first direction;
an orthographic projection of the first signal line on the base substrate is located between an orthographic projection on the base substrate of the enable signal line in the first row of pixel driving circuits and an orthographic projection on the base substrate of the second reset signal line in the first row of pixel driving circuits;
in the first row of pixel driving circuits, the minimum distance in the second direction between an orthographic projection of the enable signal line on the base substrate and an orthographic projection of the second reset signal line on the base substrate is L3;
in the second row of pixel driving circuits, the minimum distance in the second direction between an orthographic projection of the enable signal line on the base substrate and an orthographic projection of the second reset signal line on the base substrate is L4; and
L3 is larger than L4.

28. The display panel according to claim 1, wherein
the display panel comprises a pixel driving circuit and a light-emitting unit, the pixel driving circuit comprising a driving transistor, a first transistor, a second transistor, a fourth transistor, a fifth transistor, a sixth transistor, a seventh transistor, and a capacitor;
the first transistor has a first terminal connected to a first initial signal line and a second terminal connected to a gate of the driving transistor;
the second transistor has a first terminal connected to a gate of the driving transistor and a second terminal connected to a second terminal of the driving transistor;
the fourth transistor has a first terminal connected to the data line and a second terminal connected to a first terminal of the driving transistor;
the fifth transistor has a first terminal connected to a power line and a second terminal connected to a first terminal of the driving transistor;
the sixth transistor has a first terminal connected to a second terminal of the driving transistor and a second terminal connected to a first electrode of the light-emitting unit;
the seventh transistor has a first terminal connected to a second initial signal line and a second terminal connected to the first electrode of the light-emitting unit; and
the capacitor has a first electrode connected to a gate of the driving transistor and a second electrode connected to the power line.

29. The display panel according to claim 28, wherein the display panel further comprises:
a first active layer located on a side of the base substrate, wherein the first active layer comprises a third active portion, a fourth active portion, a fifth active portion, a sixth active portion, and a seventh active portion, the third active portion is used to form a channel region of the driving transistor, the fourth active portion is used to form a channel region of the fourth transistor, the fifth active portion is used to form a channel region of the fifth transistor, the sixth active portion is used to form a channel region of the sixth transistor, and the seventh active portion is used to form a channel region of the seventh transistor;
a first gate layer located on a side of the first active layer away from the base substrate, wherein the first gate layer comprises a first gate line, an enable signal line, a second reset signal line, and a first conductive portion, an orthographic projection of the first gate line on the base substrate extends along the first direction and covers an orthographic projection of the fourth active portion on the base substrate, an orthographic projection of the enable signal line on the base substrate extends along the first direction and covers orthographic projections of the fifth active portion and the sixth active portion on the base substrate, an orthographic projection of the second reset signal line on the base substrate extends along the first direction and covers an orthographic projection of the seventh active portion on the base substrate, and an orthographic projection of the first conductive portion on the base substrate covers an orthographic projection of the third active portion on the base substrate;
a second active layer located on a side of the first gate layer away from the base substrate, wherein the second active layer comprises a first active portion and a second active portion, the first active portion is used to form a channel region of the first transistor, and the second active portion is used to form a channel region of the second transistor; and
a third gate layer located on a side of the second active layer away from the base substrate, wherein the third gate layer comprises a second gate line and a first reset signal line, an orthographic projection of the second gate line on the base substrate extends along the first direction and covers an orthographic projection of the second active portion on the base substrate, and an orthographic projection of the first reset signal line on the base substrate extends along the first direction and covers an orthographic projection of the first active portion on the base substrate,
wherein an orthographic projection of the second reset signal line on the base substrate, an orthographic projection of the enable signal line on the base substrate, an orthographic projection of the first conductive portion on the base substrate, an orthographic projection of the second gate line on the base substrate, an orthographic projection of the first gate line on the base substrate, and an orthographic projection of the first reset signal line on the base substrate are arranged sequentially along the second direction.

30-32. (canceled)

33. A display apparatus, comprising a display panel, wherein the display panel comprises a display area and a fan-out area located in the display area, and the display panel further comprises:
a base substrate;
a plurality of data lines located in the display area, wherein orthographic projections of the data lines on the base substrate are arranged at intervals along a first direction and extend along a second direction, the first direction intersecting the second direction;
a plurality of first data fan-out lines located in the fan-out area, wherein orthographic projections of the first data fan-out lines on the base substrate are arranged at intervals along the second direction and extend along the first direction, and the first data fan-out line is arranged corresponding to and connected with a respective data line;
a plurality of second data fan-out lines located in the fan-out area, wherein orthographic projections of the second data fan-out lines on the base substrate are arranged at intervals along the first direction and extend along the second direction, and the second data fan-out line is arranged corresponding to and connected with a respective first data fan-out line.
